(19) United States
(12) Patent Application Publication
(10) Pub. No.: US 2023/0152701 A1
(43) Pub. Date: May 18, 2023

(54) STRUCTURE AND METHOD TO ACHIEVE POSITIVE TONE DRY DEVELOP BY A HERMETIC OVERLAYER

(71) Applicant: Lam Research Corporation, Fremont, CA (US)

(72) Inventor: Sivananda Krishnan Kanakasabapathy, Pleasanton, CA (US)

(21) Appl. No.: 17/905,632

(22) PCT Filed: Mar. 22, 2021
(86) PCT No.: PCT/US2021/023493

§ 371 Date: Sep. 2, 2022

Related U.S. Application Data
(60) Provisional application No. 63/002,240, filed on Mar. 30, 2020.

(51) Int. Cl. G03F 7/11; G03F 7/09; G03F 7/004; G03F 7/38; G03F 7/36; G03F 7/40; H01L 21/027; C23C 16/54; C23C 16/455; C23C 16/50; C23C 16/18

(52) U.S. Cl. CPC G03F 7/11; G03F 7/091; G03F 7/0042; G03F 7/38; G03F 7/36; G03F 7/40; H01L 21/0274; C23C 16/54; C23C 16/45525; C23C 16/50; C23C 16/18; G03F 7/168

(57) ABSTRACT

The present disclosure relates to stacks having a hermetic overlayer, as well as methods and apparatuses for applying such hermetic overlayers. In particular embodiments, the hermetic overlayer allows a film to be employed as a positive tone, EUV photoresist with dry development.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### FIELD

The present disclosure relates to stacks having a hermetic overlayer, as well as methods and apparatuses for applying such hermetic overlayers. In particular embodiments, the hermetic overlayer allows a film to be employed as a positive tone, EUV photoresist with dry development.

### BACKGROUND

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

Patterning of thin films in semiconductor processing is often an important step in the fabrication of semiconductors. Patterning involves lithography. In conventional photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with conventional photolithography methods. EUV light sources at approximately 10-20 nm, or 11-14 nm wavelength, for example 13.5 nm wavelength, can be used for leading-edge lithography tools, also referred to as scanners. EUV radiation is strongly absorbed in a wide range of solid and fluid materials including quartz and water vapor, and so operates in a vacuum.

### SUMMARY

The present disclosure relates to use of a hermetic overlayer disposed on a top surface of a film within a stack. In one instance, use of the hermetic overlayer protects the film from inadvertent or uncontrolled reactions, e.g., from ambient exposure to radiation, moisture, and other reactants. Such an overlayer could be beneficial for preserving an unexposed film in a pristine state and/or preserving an exposed film by sealing the latent image after EUV exposure.

Furthermore, the hermetic overlayer can allow a film to be employed as a positive tone resist. In this embodiment, the hermetic overlayer preserves any activated reactive groups or reactive bonds generated within the film after EUV exposure, thus minimizing reactions between the EUV-cleaved groups in the film with various moieties (e.g., oxygen, hydroxyl, hydrogen, moisture, etc.) present in an ambient environment. If the preserved EUV-cleaved groups are sensitive to etching, then those groups and the exposed area having those groups can be selectively removed (e.g., by way of a dry or a wet development step). In this way, the film serves as a positive tone resist.

In some embodiments, the hermetic overlayer can be configured to be EUV absorbing, thus providing beneficial photoelectrons upon EUV radiation that can be injected into the film to provide further EUV-mediated cleavage events. In this way, an EUV dose of the film could be reduced, as compared to a dose for a stack lacking the hermetic overlayer.

In other embodiments, the hermetic overlayer can be configured to simplify processing of the stack. In one instance, the overlayer can be removed by using a dry development process that can be transitioned to develop the film, e.g., by removing the EUV-exposed areas of the film. Additional details regarding the overlayer, as well as methods and apparatuses thereof, are described herein. These and other features of the disclosed embodiments will also be described in detail below with reference to the associated drawings.

In a first aspect, the present disclosure encompasses a stack including: a semiconductor substrate having a top surface; a resist film disposed on the top surface of the semiconductor substrate, wherein the resist film includes an Extreme Ultraviolet (EUV) photoresist; and a hermetic overlayer disposed on a top surface of the resist film.

In some embodiments, the overlayer is configured to protect the top surface of the resist film from absorbing one or more bond-terminating moieties (e.g., oxygen, hydroxyl, hydrogen, ambient moisture, etc.) from a gas phase.

In some embodiments, the overlayer is EUV absorbing and configured to provide a directional primary photoelectron flux to the top of the resist film upon EUV irradiation. In other embodiments, the overlayer is configured to generate one or more primary photoelectrons and/or secondary photoelectrons for injection from the overlayer to the resist film.

In particular embodiments, the overlayer has a thickness of about 1 nm to about 5 nm. In other embodiments, the overlayer includes a monolithic film including tin, tellurium, bismuth, or an oxide of any of these. In some embodiments, the overlayer includes a tin alloy. In yet other embodiments, the tin alloy further includes tellurium or bismuth.

In some embodiments, the overlayer includes a bilayer. In particular embodiments, the bilayer includes a lower layer including an alloy and an upper layer including an oxide.

In other embodiments, the overlayer has a secondary emission yield of about 0.5 to about 2. In yet other embodiments, the overlayer includes tin, tellurium, bismuth, an alloy thereof, an oxide thereof, or a complex oxide thereof.

In some embodiments, EUV photoresist includes an organometallic material (e.g., an organometallic material including tin, as well as other such materials described herein). In particular embodiments, the resist film has a thickness of about 5 nm to about 200 nm. In other embodiments, the resist film includes a dry-deposited resist or a spin-on resist.

In some embodiments, the resist film includes one or more EUV exposed areas and one or more EUV unexposed areas. In particular embodiments, a top surface of at least one EUV exposed area includes an activated metal (e.g., further including one or more dangling bonds).

In a second aspect, the present disclosure encompasses a method employing a positive tone resist, the method including: depositing a resist film on a top surface of a semiconductor substrate, wherein the resist film includes an EUV photoresist; applying a hermetic overlayer on a top surface of the resist film; patterning the resist film through the overlayer by an EUV exposure, thereby providing EUV exposed areas and EUV unexposed areas; and developing the resist film, thereby removing the EUV exposed areas and providing a pattern within the resist film. In some embodiments, the EUV exposure has a wavelength in the range of about 10 nm to about 20 nm in a vacuum ambient.

In some embodiments, the EUV exposure generates one or more primary photoelectrons and/or secondary photoelectrons for injection from the overlayer to the resist film.

In particular embodiments, the method further includes (e.g., after the depositing step): baking the film, thereby providing a post-application bake (PAB) step to remove one or more volatile components from the resist film prior to the applying step. In some embodiments, the applying step is conducted at a lower temperature than the PAB step (e.g., lower by about 10° C., 20° C., 30° C., 40° C., 50° C., 60° C., 70° C., 80° C., 90° C., or 100° C.).

In some embodiments, the applying step includes thermal atomic layer deposition, spin coat deposition, electron beam vaporization, or a combination thereof.

In other embodiments, the method further includes (e.g., after the patterning step): stripping the overlayer, thereby providing a photoresist stack having the EUV exposed areas and the EUV unexposed areas.

In yet other embodiments, the method further includes (e.g., after the stripping step): conducting in situ metrology of the photoresist stack (e.g., conducting scatterometry).

In some embodiments, the stripping step includes a thermal dry etch or a downstream plasma process. In other embodiments, the stripping step and the developing step are conducted in vacuum without a vacuum break. In yet other embodiments, the stripping step and the developing step are conducted employing halide chemistry (e.g., HBr chemistry or any described herein). In particular embodiments, the stripping step and the developing step are conducted at a pressure of about 1 mTorr to about 100 mTorr. In other embodiments, the stripping step and the developing step are conducted at a temperature of about −10° C. to about 100° C.

In some embodiments, the method further includes (e.g., after the developing step): hardening the EUV unexposed areas, thereby providing a photoresist mask. In particular embodiments, the hardening step includes exposing with vacuum ultraviolet (VUV) in an oxygen (O₂), argon (Ar), helium (He), or carbon dioxide (CO₂) plasma environment. In other embodiments, the hardening step includes annealing at a temperature of about 180° C. to about 240° C. in an air ambient environment or in an ozone/O₂ ambient environment.

In a third aspect, the present disclosure features a method for forming a hermetic overlayer, the method including: depositing a resist film on a top surface of a semiconductor substrate, wherein the film includes an EUV photoresist; applying a hermetic overlayer on a top surface of the resist film; and patterning the resist film through the overlayer by an EUV exposure. In some embodiments, the EUV exposure has a wavelength in the range of about 10 nm to about 20 nm in a vacuum ambient.

In some embodiments, the EUV exposure generates one or more primary photoelectrons and/or secondary photoelectrons for injection from the overlayer to the resist film.

In particular embodiments, the method further includes (e.g., after the depositing step): baking the film, thereby providing a post-application bake (PAB) step to remove one or more volatile components from the resist film prior to the applying step. In some embodiments, the applying step is conducted at a lower temperature than the PAB step (e.g., lower by about 10° C., 20° C., 30° C., 40° C., 50° C., 60° C., 70° C., 80° C., 90° C., or 100° C.).

In some embodiments, the applying step includes thermal atomic layer deposition, spin coat deposition, electron beam vaporization, or a combination thereof.

In some embodiments, the method further includes (e.g., after the patterning step): stripping the overlayer, thereby providing a photoresist stack having EUV exposed areas and EUV unexposed areas; and developing the resist film, thereby removing the EUV exposed areas and providing a pattern within the resist film.

In other embodiments, the method further includes (e.g., after the stripping step): conducting in situ metrology of the photoresist stack (e.g., conducting scatterometry).

In some embodiments, the stripping step includes a thermal dry etch or a downstream plasma process. In other embodiments, the stripping step and the developing step are conducted in vacuum without a vacuum break. In yet other embodiments, the stripping step and the developing step are conducted employing halide chemistry (e.g., HBr chemistry or any described herein). In particular embodiments, the stripping step and the developing step are conducted at a pressure of about 1 mTorr to about 100 mTorr. In other embodiments, the stripping step and the developing step are conducted at a temperature of about −10° C. to about 100° C.

In some embodiments, the method further includes (e.g., after the developing step): hardening the EUV unexposed areas, thereby providing a photoresist mask. In particular embodiments, the hardening step includes exposing with vacuum ultraviolet (VUV) in an O₂, Ar, He, or CO₂ plasma environment. In other embodiments, the hardening step includes annealing at a temperature of about 180° C. to about 240° C. in an air ambient environment or in an ozone/O _{ambient} environment.

In a fourth aspect, the present disclosure features a method for developing a stack, the method including: providing a stack having a hermetic overlayer; patterning the stack through the overlayer by an EUV exposure (e.g., having a wavelength in the range of about 10 nm to about 20 nm in a vacuum ambient); stripping the overlayer, thereby providing a photoresist stack having EUV exposed areas and EUV unexposed areas; and developing the stack. In some embodiments, the developing step results in removing the EUV exposed areas, thereby providing a pattern within the stack.

In some embodiments, the stack includes a semiconductor substrate having a top surface; a resist film disposed on the top surface of the semiconductor substrate, wherein the resist film includes an EUV photoresist; and a hermetic overlayer disposed on a top surface of the resist film.

In some embodiments, the stripping step includes a thermal dry etch or a downstream plasma process. In other embodiments, the stripping step and the developing step are conducted in vacuum without a vacuum break. In yet other embodiments, the stripping step and the developing step are conducted employing halide chemistry (e.g., HBr chemistry or any described herein). In particular embodiments, the stripping step and the developing step are conducted at a pressure of about 1 mTorr to about 100 mTorr. In other embodiments, the stripping step and the developing step are conducted at a temperature of about −10° C. to about 100° C.

In other embodiments, the method further includes (e.g., after the stripping step): conducting in situ metrology of the photoresist stack (e.g., conducting scatterometry).

In some embodiments, the method further includes (e.g., after the developing step): hardening the EUV unexposed areas, thereby providing a photoresist mask. In particular embodiments, the hardening step includes exposing with vacuum ultraviolet (VUV) in an O₂, Ar, He, or CO₂ plasma environment. In other embodiments, the hardening step includes annealing at a temperature of about 180° C. to about 240° C. in an air ambient environment or in an ozone/O₂ ambient environment.

In a fifth aspect, the present invention features an apparatus for depositing a hermetic overlayer. In particular embodiments, the apparatus includes a deposition module including a chamber for depositing an EUV photoresist as a resist film; an application module including a chamber for applying a hermetic overlayer; a patterning module including an EUV photolithography tool with a source of sub-30 nm wavelength radiation; and/or a development module including a chamber for stripping the overlayer and developing the resist film.

In other embodiments, the apparatus includes a controller including one or more memory devices, one or more processors, and system control software coded with instructions for conducting overlayer deposition, the instructions including instructions for performing any steps of methods described herein. In some embodiments, the instructions include (e.g., in the deposition module) depositing the resist film on a top surface of a semiconductor substrate, wherein the resist film includes the EUV photoresist. In other embodiments, the instructions include (e.g., in the application module) applying the overlayer on a top surface of the resist film. In yet other embodiments, the instructions include (e.g., in the patterning module) patterning the resist film through the overlayer with sub-30 nm resolution directly by EUV exposure having a wavelength in the range of about 10 nm to about 20 nm in a vacuum ambient, thereby forming a pattern through the overlayer and within the resist film. In other embodiments, the instructions include (e.g., in the development module) stripping the overlayer to provide a photoresist stack including EUV exposed areas and EUV unexposed areas; and developing the resist film to remove the EUV exposed areas and to provide the pattern within the resist film.

In some embodiments, according to the instructions, the stripping step includes a thermal dry etch or a downstream plasma process. In other embodiments, according to the instructions, the stripping step and the developing step are conducted in vacuum without a vacuum break. In yet other embodiments, according to the instructions, the stripping step and the developing step are conducted employing HBr chemistry. In some embodiments, according to the instructions, the stripping step and the developing step are conducted at a pressure of about 1 mTorr to about 100 mTorr. In other embodiments, according to the instructions, the stripping step and the developing step are conducted at a temperature of about −10° C. to about 100° C.

In particular embodiments, instructions further include (e.g., in the development module): hardening the EUV unexposed areas, thereby providing a photoresist mask. In further embodiments, according to the instructions, the hardening step includes annealing at a temperature of about 180° C. to about 240° C. in an air ambient environment or in an ozone/O₂ ambient environment.

In other embodiments, the apparatus further includes: an in situ metrology module including a spectroscopy tool to analyze the photoresist stack. In some embodiment, the instructions further include (e.g., in the in situ metrology module): conducting one or more spectroscopic analyses of the stack (e.g., after the stripping step, before or after the patterning step, or before or after the developing step).

In any embodiment herein, the overlayer can be configured to generate one or more primary photoelectrons and/or secondary photoelectrons for injection from the overlayer to the resist film. In some embodiments, the overlayer has a secondary emission yield of about 0.5 to about 2.

In any embodiment herein, the photoresist layer and/or overlayer can include any EUV-sensitive material described herein. In particular embodiments, the overlayer includes tin, tellurium, bismuth, an alloy thereof, an oxide thereof, or a complex oxide thereof,

In any embodiment herein, the overlayer can have a thickness of about 1 nm to about 5 nm. In other embodiments, the overlayer includes a monolithic film including tin, tellurium, bismuth, or an oxide of any of these. In some embodiments, the overlayer includes a tin alloy.

In yet other embodiments, the tin alloy further includes tellurium or bismuth.

In any embodiment herein, the overlayer can include a bilayer. In some embodiments, the bilayer includes a lower layer including an alloy and an upper layer including an oxide.

In any embodiment herein, the EUV photoresist can include an organometallic material (e.g., any described herein). In particular embodiments, the organometallic material includes tin.

In any embodiment herein, the resist film and/or the hermetic overlayer can include a dry-deposited resist or a spin-on resist.

In any embodiment herein, the resist film can include one or more EUV exposed areas and one or more EUV unexposed areas. In particular embodiments, a top surface of at least one EUV exposed area includes an activated metal including one or more dangling bonds.

In any embodiment herein, the EUV exposure can have a wavelength of 13.5 nm.

Additional embodiments are described herein.

### Definitions

By “acyloxy” or “alkanoyloxy,” as used interchangeably herein, is meant an acyl or alkanoyl group, as defined herein, attached to the parent molecular group through an oxy group. In particular embodiments, the alkanoyloxy is —O—C(O)-Ak, in which Ak is an alkyl group, as defined herein. In some embodiments, an unsubstituted alkanoyloxy is a C₂₋₇ alkanoyloxy group. Exemplary alkanoyloxy groups include acetoxy.

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl. Non-limiting unsubstituted alkenyl groups include allyl and vinyl.

By “alkenylene” is meant a multivalent (e.g., bivalent) form of an alkenyl group, which is an optionally substituted C₂₋₂₄ alkyl group having one or more double bonds. The alkenylene group can be cyclic (e.g., C₃₋₂₄ cycloalkenyl) or acyclic. The alkenylene group can be substituted or unsubstituted. For example, the alkenylene group can be substituted with one or more substitution groups, as described herein for alkyl. Exemplary, non-limiting alkenylene groups include —CH═CH— or —CH═CHCH₂—.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl (Me), ethyl (Et), n-propyl (n-Pr), isopropyl (i-Pr), cyclopropyl, n-butyl (n-Bu), isobutyl (i-Bu), s-butyl (s-Bu), t-butyl (t-Bu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O)H); (8) carboxyl (e.g., —CO₂H); (9) C₃₋₈ cycloalkyl (e.g., a monovalent saturated or unsaturated non-aromatic cyclic C₃₋₈ hydrocarbon group); (10) halo (e.g., F, Cl, Br, or I); (11) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)—Het, wherein Het is heterocyclyl, as described herein); (14) hydroxyl (e.g., —OH); (15) N-protected amino; (16) nitro (e.g., —NO₂); (17) oxo (e.g., ═O); (18) —CO₂R^{A}, where R^{A} is selected from the group consisting of (a) C₁₋₆ alkyl, (b) C₄₋₁₈ aryl, and (c) (C₄₋₁₈ aryl) C₁₋₆ alkyl (e.g., -Lk-Ar, wherein Lk is a bivalent form of optionally substituted alkyl group and Ar is optionally substituted aryl); (19) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -Lk-Cy, wherein Lk is a bivalent form of optionally substituted alkyl group and Cy is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl.

By “alkynylene” is meant a multivalent (e.g., bivalent) form of an alkynyl group, which is an optionally substituted C₂₋₂₄ alkyl group having one or more triple bonds. The alkynylene group can be cyclic or acyclic. The alkynylene group can be substituted or unsubstituted. For example, the alkynylene group can be substituted with one or more substitution groups, as described herein for alkyl. Exemplary, non-limiting alkynylene groups include —C≡C— or —C≡CCH₂—.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for alkyl or aryl.

By “(aryl)(alkyl)ene” is meant a bivalent form including an arylene group, as described herein, attached to an alkylene or a heteroalkylene group, as described herein. In some embodiments, the (aryl)(alkyl)ene group is -L-Ar— or -L-Ar-L- or —Ar-L-, in which Ar is an arylene group and each L is, independently, an optionally substituted alkylene group or an optionally substituted heteroalkylene group.

By “carbonyl” is meant a —C(O)— group, which can also be represented as >C═O, or a —CO group.

By “carboxyl” is meant a —CO₂H group.

By “carboxyalkyl” is meant an alkyl group, as defined herein, substituted by one or more carboxyl groups, as defined herein.

By “carboxyaryl” is meant an aryl group, as defined herein, substituted by one or more carboxyl groups, as defined herein.

By “cyclic anhydride” is meant a 3-, 4-, 5-, 6- or 7-membered ring (e.g., a 5-, 6- or 7-membered ring), unless otherwise specified, having a —C(O)—O—C(O)— group within the ring. The term “cyclic anhydride” also includes bicyclic, tricyclic and tetracyclic groups in which any of the above rings is fused to one, two, or three rings independently selected from the group consisting of an aryl ring, a cyclohexane ring, a cyclohexene ring, a cyclopentane ring, a cyclopentene ring, and another monocyclic heterocyclic ring. Exemplary cyclic anhydride groups include a radical formed from succinic anhydride, glutaric anhydride, maleic anhydride, phthalic anhydride, isochroman-1,3-dione, oxepanedione, tetrahydrophthalic anhydride, hexahydrophthalic anhydride, pyromellitic dianhydride, naphthalic anhydride, 1,2-cyclohexanedicarboxylic anhydride, etc., by removing one or more hydrogen. Other exemplary cyclic anhydride groups include dioxotetrahydrofuranyl, dioxodihydroisobenzofuranyl, etc. The cyclic anhydride group can also be substituted or unsubstituted. For example, the cyclic anhydride group can be substituted with one or more groups including those described herein for heterocyclyl.

By “cycloalkenyl” is meant a monovalent unsaturated non-aromatic or aromatic cyclic hydrocarbon group of from three to eight carbons, unless otherwise specified, having one or more double bonds. The cycloalkenyl group can also be substituted or unsubstituted. For example, the cycloalkenyl group can be substituted with one or more groups including those described herein for alkyl.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “halo” is meant F, Cl, Br, or I.

By “haloalkyl” is meant an alkyl group, as defined herein, substituted with one or more halo.

By “heteroalkyl” is meant an alkyl group, as defined herein, containing one, two, three, or four non-carbon heteroatoms (e.g., independently selected from the group consisting of nitrogen, oxygen, phosphorous, sulfur, selenium, or halo).

By “heteroalkylene” is meant a bivalent form of an alkylene group, as defined herein, containing one, two, three, or four non-carbon heteroatoms (e.g., independently selected from the group consisting of nitrogen, oxygen, phosphorous, sulfur, selenium, or halo). The heteroalkylene group can be substituted or unsubstituted. For example, the heteroalkylene group can be substituted with one or more substitution groups, as described herein for alkyl.

By “heterocyclyl” is meant a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl benzylsultimyl, bipyrazinyl, bipyridinyl, carbazolyl (e.g., 4H-carbazolyl), carbolinyl (e.g., (3-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for alkyl.

By “hydrocarbyl” is meant a univalent group formed by removing a hydrogen atom from a hydrocarbon. Non-limiting unsubstituted hydrocarbyl groups include alkyl, alkenyl, alkynyl, and aryl, as defined herein, in which these groups include only carbon and hydrogen atoms. The hydrocarbyl group can be substituted or unsubstituted. For example, the hydrocarbyl group can be substituted with one or more substitution groups, as described herein for alkyl. In other embodiments, any alkyl or aryl group herein can be replaced with a hydrocarbyl group, as defined herein.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like.

By “hydroxyaryl” is meant an aryl group, as defined herein, substituted by one to three hydroxyl groups, with the proviso that no more than one hydroxyl group may be attached to a single carbon atom of the aryl group and is exemplified by hydroxyphenyl, dihydroxyphenyl, and the like.

By “isocyanato” is meant —NCO.

By “oxido” is meant an —O⁻ group.

By “oxo” is meant an ═O group.

By “phosphine” is meant a trivalent or tetravalent phosphorous having hydrocarbyl moieties. In some embodiments, phosphine is a —PR^{P}₃ group, where each R^{p} is, independently, H, optionally substituted alkyl, or optionally substituted aryl. The phosphine group can be substituted or unsubstituted. For example, the phosphine group can be substituted with one or more substitution groups, as described herein for alkyl.

By “selenol” is meant an —SeH group.

By “tellurol” is meant an —TeH group.

By “thioisocyanato” is meant —NCS.

By “thiol” is meant an —SH group.

As used herein, the term “about” means+/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Other features and advantages of the invention will be apparent from the following description and the claims.

### BRIEF DESCRIPTION OF THE DRAWINGS

FIG. 1A-1C presents schematic diagrams of exemplary stacks. Provided are (A) a stack including an exemplary hermetic overlayer 103; (B) a schematic showing photoelectron flux between the hermetic overlayer 103 and the film 102; and (C) a stack showing an exemplary hermetic overlayer 113 as a bilayer having an upper layer 113a and a lower layer 113b.

FIG. 2A-2C presents schematic illustrations of exemplary methods to provide a positive tone resist. Provided are (A) a first exemplary method 200 employing a stack 210 and (B-C) a second exemplary method 250a, 250b including steps to deposit 251 a resist film and apply 253 a hermetic overlayer.

FIG. 3A-3E presents flow diagrams of exemplary methods using a hermetic overlayer. Provided are (A) a first exemplary method 300; (B) a second exemplary method 320 including wet deposition 322 of a photoresist (PR) and dry development 336 of the PR pattern; (C) a third exemplary method 340 including dry deposition 342 of a PR and wet development 356 of the PR pattern; (D) a fourth exemplary method 360 including dry deposition 362 of a PR and dry development 376 of the PR pattern; and (E) a fifth exemplary method 380 including dry deposition 382 of a PR, wet post-deposition processing 384, and dry development 396 of the PR pattern.

FIG. 4 presents a schematic illustration of an embodiment of a process station 400 for dry development.

FIG. 5 presents a schematic illustration of an embodiment of a multi-station processing tool 500.

FIG. 6 presents a schematic illustration of an embodiment of an inductively coupled plasma apparatus 600.

FIG. 7 presents a schematic illustration of an embodiment of a semiconductor process cluster tool architecture 700.

### DETAILED DESCRIPTION

This disclosure relates generally to the field of semiconductor processing. In particular aspects, the disclosure is directed to methods and apparatuses that employ EUV photoresists in combination with a hermetic overlayer (HerO). In some embodiments, processing of EUV photoresists (e.g., EUV-sensitive metal and/or metal oxide-containing resist films) can include EUV patterning and EUV patterned film development to form a patterning mask.

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

EUV lithography makes use of EUV resists that are patterned to form masks for use in etching underlying layers. EUV resists may be polymer-based chemically amplified resists (CARs) produced by liquid-based spin-on techniques. An alternative to CARs is directly photopatternable metal oxide-containing films, such as those available from Inpria Corp. (Corvallis, Oreg.), and described, for example, in U.S. Pat Pub. Nos. US 2017/0102612, US 2016/0216606, and US 2016/0116839, incorporated by reference herein at least for their disclosure of photopatternable metal oxide-containing films. Such films may be produced by spin-on techniques or dry vapor-deposited. The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled EUV PHOTOPATTERNING OF VAPOR-DEPOSITED METAL OXIDE-CONTAINING HARDMASKS, and/or in International Appl. No. PCT/US19/31618, filed May 9, 2019, published as International Pub. No. WO2019/217749 and titled METHODS FOR MAKING EUV PATTERNABLE HARD MASKS, the disclosures of which at least relating to the composition, deposition, and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the mask.

Directly photopatternable EUV resists may be composed of or contain metals and/or metal oxides mixed within organic components. The metals/metal oxides are highly promising in that they can enhance the EUV photon adsorption, generate secondary electrons, and/or show increased etch selectivity to an underlying film stack and device layers. Up to date, these resists have been developed using a wet (solvent) approach, which requires the wafer to move to the track, where it is exposed to developing solvent, dried, and then baked. This wet development step does not only limit productivity but can also lead to line collapse due to surface tension effects during the evaporation of solvent between fine features.

Generally, resists can be employed as a positive tone resist or a negative tone resist by controlling the chemistry of the resist and/or the solubility or reactivity of the developer. It would be beneficial to have an EUV resist that can serve as either a negative tone resist or a positive tone resist.

### Hermetic Overlayers and Stacks Thereof

The present disclosure relates to use of hermetic overlayers and describes various structural aspects of such an overlayer. In particular embodiments, the overlayer is employed within a stack, in which the overlayer is disposed on a top surface of a film (e.g., a photoresist film, which can be employed as an imaging layer). Furthermore, use of such an overlayer includes methods for depositing an overlayer to obtain a stack, as well as methods of employing a stack in order to achieve a positive tone film with dry development. Details of such methods are described herein.

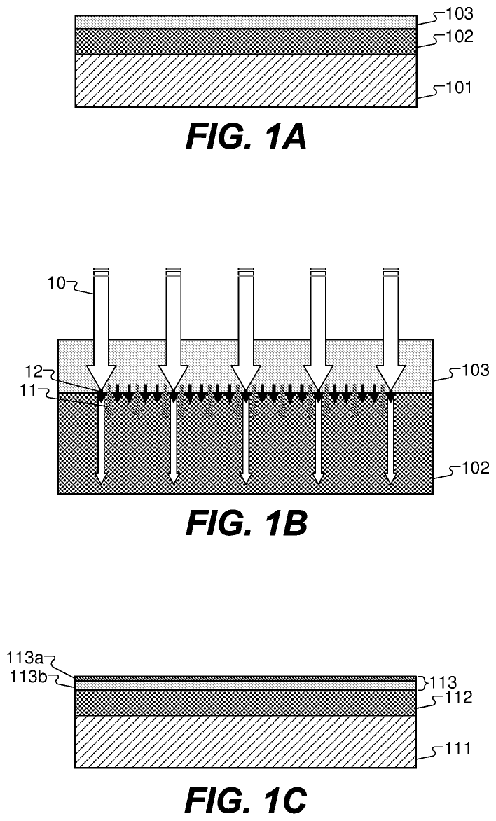

FIG. 1A provides an exemplary stack including a substrate 101 (e.g., a semiconductor substrate) having a top surface, a film 102 disposed on the top surface of the substrate 101, and a hermetic overlayer 103 disposed on a top surface of the film 102. The film can include any useful EUV-sensitive material (e.g., any described herein) or photoresist (PR). The material in the hermetic overlayer and the film can be the same or different.

In various embodiments, the hermetic overlayer protects the PR film from inadvertent reactions with moieties within an ambient environment. For instance, when the film is an EUV-sensitive film, the hermetic overlayer can protect the film from inadvertent, uncontrolled exposure to oxygen, moisture, and stray radiation, such as EUV or deep-UV radiation. In some instances, the hermetic overlayer can protect EUV exposed areas within the PR film from inadvertent reactions. As described herein, the resist can include one or more metals and one or more labile ligands (e.g., alkyl groups). Generally, upon exposure of an EUV resist to EUV radiation, the labile ligands within the resist are cleaved, thus generating activated reactive centers (e.g., reactive dangling metal bonds, metal-H groups, cleaved metal-ligand groups, or dimerized metal bonds) within the exposed areas of the resist. These reactive centers can further react at the surface with ambient moieties, e.g., oxygen, hydroxyl, hydrogen, ambient moisture, etc. In this application, the overlayer can be employed to protect those activated reactive centers within the resist from reacting at the surface with ambient moieties. In one embodiment, such moieties can include one or more bond-terminating moieties from a gas phase that can be absorbed to a top surface of the film. Such protection can be useful during stack processing, such as during transfer of the latent image (provided after EUV exposure) from the EUV scanner to the development/strip chamber.

The hermetic overlayer can provide other benefits as well. Due to the presence of the overlayer, alkenes potentially released after EUV exposure (e.g., by way of β-hydride elimination) would not be released in the sensitive EUV scanner but, instead, in the dry development tool. In addition, transfers during processing provide inherently variable Queue time (Q-time) delays, and the presence of the hermetic overlayer could mitigate the variability that could arise if such activated reactive centers were not protected.

Typically, after EUV exposure, there exists a maximal difference in metal-ligand bond density between the exposed and unexposed areas. Strong Q-time control can be typically required between exposure and further processing, in order to minimize any inadvertent oxidation/hydroxylation or hydrogenation of the metal dangling bonds formed from the freshly severed metal-ligand bonds from EUV exposure.

Such EUV-activated reactive centers, which can lack the protective but labile ligands, are generally sensitive to etching. If the hermetic overlayer preserves the EUV-activated reactions centers, then etching processes can selectively etch the EUV exposed areas, thus providing a resist having a positive tone. In some embodiments, the stack can be processed by removing the hermetic overlayer without corrupting the reticle information coded in the latent image from EUV exposure and then, without a vacuum break (thus further reducing the downsides of a lengthy Q-time), dry developing the film to selectively etch the exposed areas of the film. In yet other embodiments, as described herein, the hermetic overlayer can be mildly EUV absorbing, thus providing a directional primary photoelectron flux to the top of the resist and hence potentially lowering the required EUV dose.

The hermetic overlayer can be composed of any useful material. In one instance, the material is selected to be EUV absorbing. Exemplary EUV absorbing materials include a metal, such as tin, tellurium, or bismuth; a metal oxide, such as tin oxide (e.g., SnO₂), tellurium oxide (e.g., TeO₂), and bismuth oxide (e.g., Bi₂O₃); or an alloy, such as tin alloys (e.g., a tin telluride alloy or a tin bismuth alloy, including an alloy having about 60% tin or above); or a combination thereof. In another instance, the EUV-absorbing material is an EUV-sensitive material, such as any described herein.

The hermetic overlayer can have any useful degree of hermeticity. In one embodiment, the amount of water diffusion through the hermetic overlayer is less than about 5% over any useful time period (e.g., about one hour). In particular embodiments, the time period is comparable to the typical Q-time delay between deposition of the overlayer and EUV exposure or between EUV exposure and development. Typical Q-time delays can be about one hour. The amount of water can be measured with any useful analytic techniques, such as Fourier-transform infrared spectroscopy (FTIR, e.g., of) or X-ray photoelectron spectroscopy (XPS) of any useful bond or atom (e.g., O) determined before and after such Q-times.

Furthermore, the hermetic overlayer can be configured to provide a directional photoelectron (e.g., primary photoelectron) flux upon EUV radiation, in which the flux extends from the overlayer and into the underlying PR film. In particular embodiments, the overlayer can have a thickness that is less than the Beer's decay length of a primary photoelectron within the film. Exemplary thicknesses for the overlayer include less than about 5 nm, e.g., of from about 1 nm to about 5 nm, such as from about 1 nm to 2 nm, 1 nm to 3 nm, 1 nm to 4 nm, 2 nm to 3 nm, 2 nm to 4 nm, 2, 2 nm to 5 nm, 3 nm to 4 nm, 3 nm to 5 nm, or 4 nm to 5 nm. In embodiments including a plurality of layers (e.g., as in a bilayer), each layer can have a thickness of from about 1 nm to about 3 nm or 1 nm to 2 nm.

FIG. 1B provides a schematic showing EUV radiation 10 of an exemplary stack, in which radiation through the hermetic overlayer 103 results in attenuated EUV radiation through the film 102, as well as the production of primary photoelectrons 11 (e.g., anisotropic energetic photoelectrons having about 87 eV) and secondary photoelectrons 12 (e.g., isotropic lower energy photoelectrons having less than about 5 eV) that are injected from the overlayer 103 and into the film 102. In one embodiment, use of the hermetic overlayer during patterning results in a reduced EUV dose, as compared to patterning without the overlayer. Without wishing to be limited by mechanism, the overlayer can generate a directional flux of primary and/or secondary photoelectrons into the film, thereby providing additional radiation to pattern the film. In order to achieve such a directed flux of photoelectrons, the overlayer can be thinner than the typical mean fee length of primary electrons and yet thick enough to be a hermetic seal. Hence, an exemplary thickness of 5 nm could prevent loss of too much EUV radiation in the overlayer at the expense of the resist, by compensating partly in electron flux. Accordingly, in some embodiments, the overlayer can have any useful thickness less than 5 nm (e.g., about 2 nm to about 3 nm).

Such EUV-absorbing and EUV-sensitive materials (e.g., any described herein) can have any useful structure within the overlayer. In one embodiment, the overlayer is a monolithic film including such a material. In another embodiment, the overlayer is a layered film (e.g., a bilayer film) having a lower layer and an upper layer. In particular embodiments, the film has a thickness of from about 5 nm to about 200 nm, and the hermetic overlayer has a thickness of from about 1 nm to about 5 nm.

FIG. 1C provides a stack having a substrate 111, a film 112 disposed on a top surface of the substrate 111, and a hermetic overlayer 113 disposed on a top surface of the film 112. In one non-limiting instance, the overlayer 113 is a bilayer including a lower layer 113b in proximity to the film and an upper layer 113a in proximity to a top surface of the entire stack. The composition of the layers can be selected to optimize EUV beam absorption and/or directional flux of photoelectrons. In one instance, the lower layer includes an alloy (e.g., any described herein), and the upper layer includes an oxide (e.g., any described herein, such as a metal oxide or a metal alloy oxide). The upper layer can be formed by oxidation of the lower layer or by deposition of an oxide (e.g., a metal oxide) upon a top surface of the lower layer.

Such EUV-absorbing and EUV-sensitive materials can be deposited in any useful manner, as described herein. Exemplary deposition techniques include atomic layer deposition (ALD) (e.g., thermal ALD and plasma-enhanced ALD (PE-ALD)), spin-coat deposition, physical vapor deposition (PVD) including PVD co-sputtering, chemical vapor deposition (CVD), plasma enhanced CVD (PE-CVD), low pressure CVD (LP-CVD), sputter deposition, electron-beam (e-beam) deposition including e-beam co-evaporation, etc., or a combination thereof.

### Methods Employing a Positive Tone Resist

An exemplary method for employing a positive tone resist can include steps of providing a stack having a hermetic overlayer and a film, patterning the film through the overlayer to provide EUV exposed areas and EUV unexposed areas, and developing the film by removing the EUV exposed areas. As discussed herein, the presence of the hermetic overlayer facilitates preservation of activated reactive centers (e.g., reactive metal-H groups or cleaved metal-ligand groups) provided during patterning, which can then be removed by developing the film. Such positive tone resists can be useful for particular darkfield level applications, such to provide cut masks or to modify via levels.

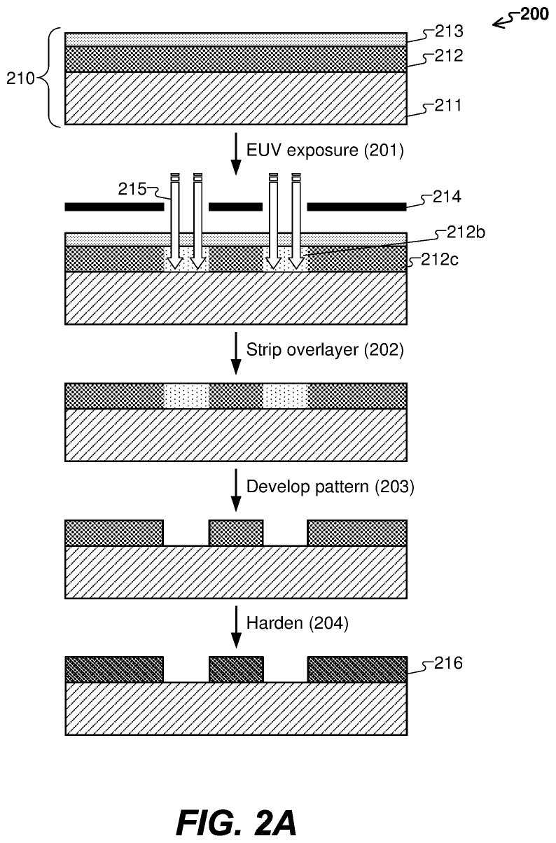

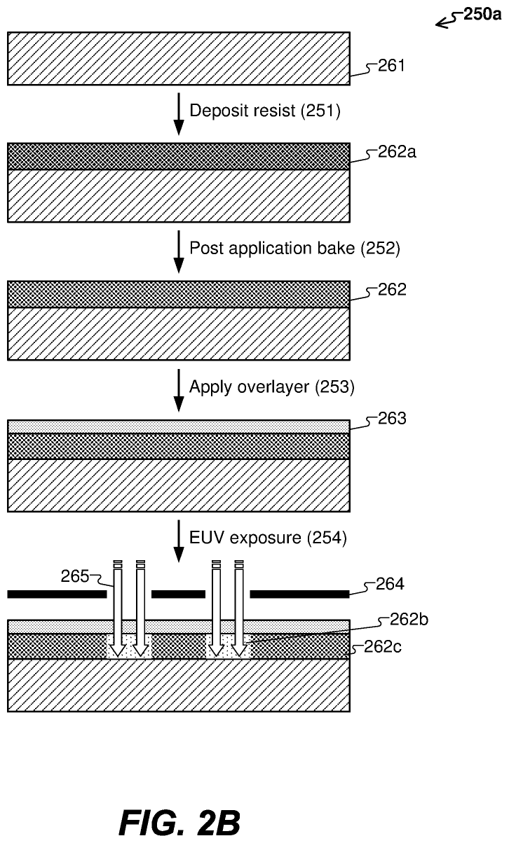

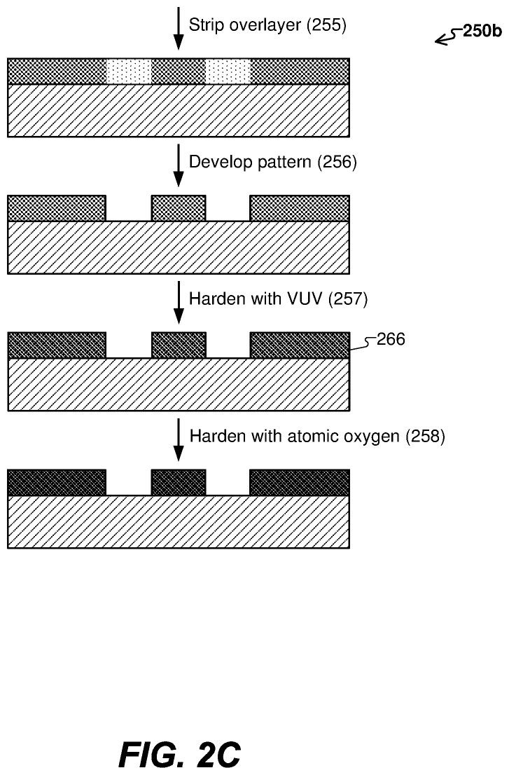

Various steps, operations, and apparatuses for such patterning and developing steps include those useful for lithography processes, as well as any described herein. For instance, FIG. 2A provides an exemplary method 200 to provide a positive tone resist, in which EUV exposed areas can be removed. As can be seen, the method 200 includes providing a stack 210 having a substrate 211 with a top surface, a film 212 disposed on the top surface of the substrate 211, and a hermetic overlayer 213 disposed on a top surface of the film 212. As described herein, the film includes an EUV-sensitive material, and the overlayer can include an EUV-absorbing or EUV-sensitive material, as described herein.

The method 200 can further include patterning the film by an EUV exposure 201. Patterning can include use of a mask 214 having EUV transparent regions and EUV opaque regions, in which EUV beams 215 are transmitted through the EUV transparent region, into the overlayer 213, and then into the film 212. In this manner, the film includes EUV unexposed areas 212c and EUV exposed areas 212b having activated reactive centers, which in turn are protected from further reaction by the presence of a hermetic overlayer 213.

The method can further include stripping 202 the overlayer, thereby removing at least a portion of the overlayer and providing a photoresist stack having accessible EUV exposed areas and EUV unexposed areas. Removal can include any useful methods to etch, develop, mill, strip, and/or lift-off a stack, a layer, a substrate, or a portion thereof. Additional development processes are described herein.

An additional step includes developing 203 the film, thereby selectively removing the EUV exposed areas 212b and maintaining the EUV unexposed areas 212c, which in turn provides a pattern within the film. Finally, the method can include an optional step of hardening 204 the patterned film, thereby providing an EUV mask 216 disposed on a top surface of the substrate 211.

The stripping and developing steps can be conducted under the same or different conditions, such as any described herein for a development process (e.g., a dry development process). In one embodiment, both the stripping and developing steps can include use of halide chemistry (e.g., HBr chemistry) in a gas phase. Such stripping and/developing steps can include any useful experimental conditions, such as a low pressure condition (e.g., of from about 1 mTorr to about 100 mTorr), a plasma exposure (e.g., in the presence of vacuum) and/or a thermal condition (e.g., of from about −10° C. to about 100° C.), that may be combined with any useful chemistry (e.g., halide chemistry). Additional development process conditions are described herein.

The method can include further steps to prepare the stack having an overlayer. Accordingly, FIG. 2B-2C provides yet another exemplary method 250a, 250b of employing a positive tone resist including the steps of providing a substrate 261 and depositing 251 a photoresist layer 262a on a top surface of the substrate 261. Optionally, the method can include conducting a post application bake (PAB) step 252 to release residual moisture from the photoresist layer 262a, thereby providing a film 262 including the EUV-sensitive material.

Next, the method 250a can include applying 253 a hermetic overlayer 263 on a top surface of the film 262 and patterning the film through the overlayer by an EUV exposure 254 (e.g., an exposure having a wavelength in the range of about 10 nm to about 20 nm in a vacuum ambient). Patterning can include use of a mask 264 having EUV transparent regions and EUV opaque regions, in which EUV beams 265 are transmitted through the EUV transparent region, into the overlayer 263, and then through the film 262. After patterning, the film includes EUV exposed areas 262b having activated reactive centers and EUV unexposed areas 262c, in which these areas are protected by the presence of a hermetic overlayer 263.

To provide a mask, the method 250b can further include stripping 255 the overlayer, developing 256 the film, and optionally hardening 257, 258 the patterned film to provide a resist mask 266. Hardening steps can include any useful process to further crosslink or react the EUV unexposed areas. Exemplary hardening steps can include exposing to plasma, annealing, thermal baking, or combinations thereof that can be useful for a post development baking (PDB) step. In particular embodiments, hardening can include exposure to vacuum ultraviolet (VUV) 257, optionally in the presence of an O₂, Ar, He, or CO₂ plasma environment; or thermal annealing (e.g., at a temperature of about 180° C. to about 240° C.), optionally in the presence of an air ambient environment or atomic oxygen 258 or in the presence of an ozone/O₂ ambient environment.

In some instances, any of the patterning, stripping, and developing steps described above and below can be conducted on a stack that includes a hermetic overlayer. Such steps can provide a method for developing a stack, a method employing a positive tone resist, or any other useful end described herein.

### Methods Employing a Hermetic Overlayer

In addition to particularized methods to provide a positive tone resist, the present disclosure generally includes any useful method that employs a hermetic overlayer. Such methods can include any useful lithography processes, deposition processes, EUV exposure processes, development processes, and post-application processes, as described herein.

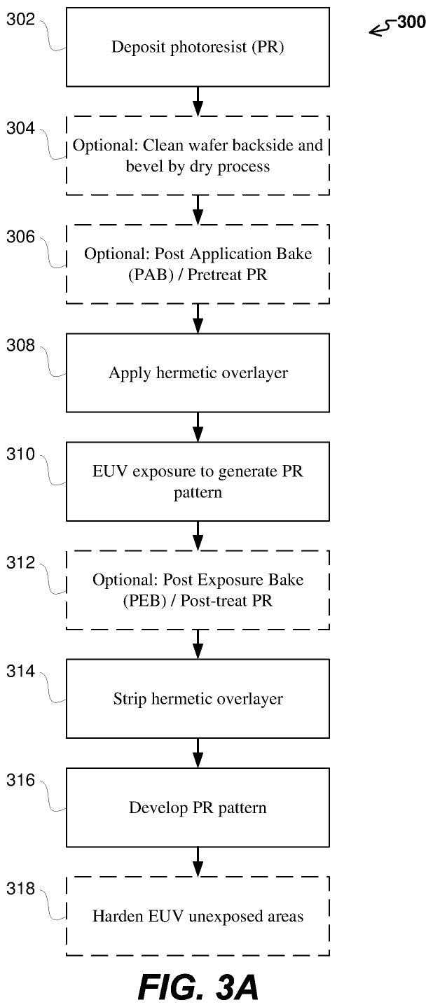

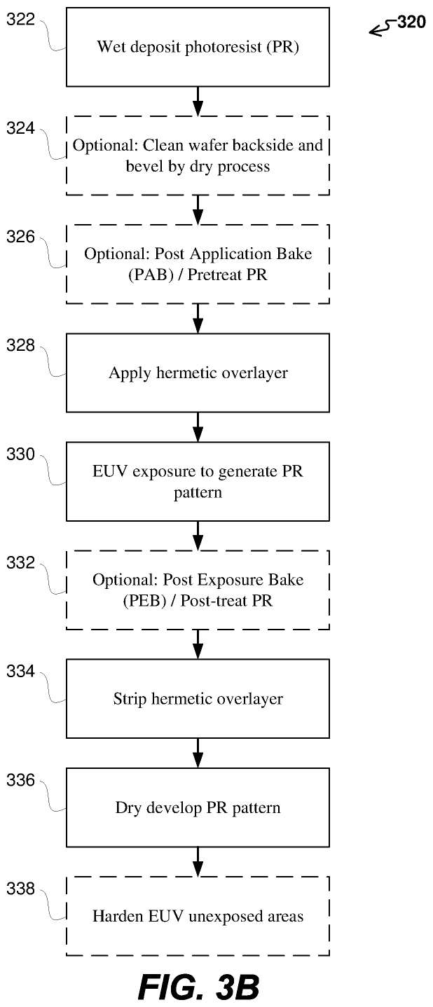

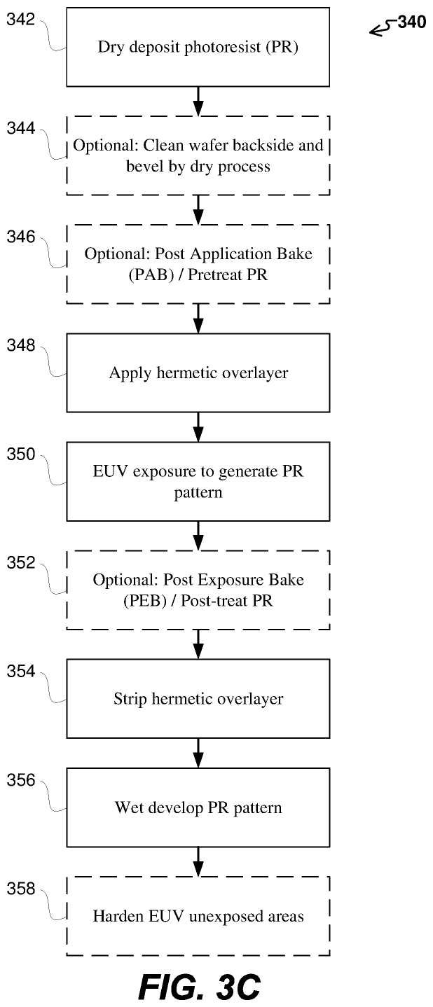

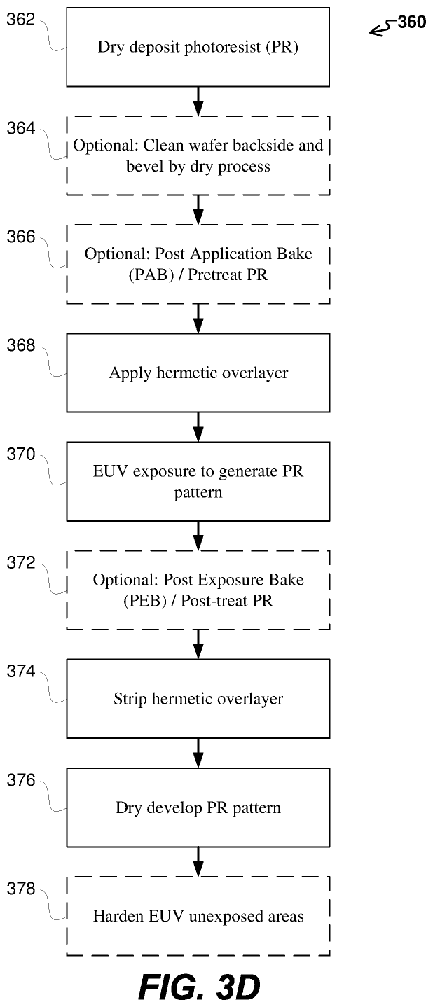

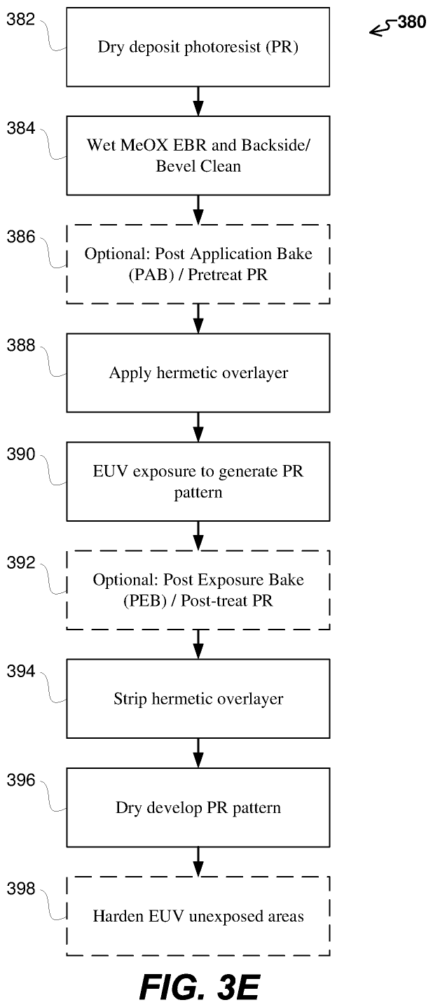

FIG. 3A provides an exemplary method for forming a hermetic overlayer, in which the method 300 includes depositing 302 a photoresist as a film on a top surface of a substrate, wherein the film includes an EUV-sensitive material; applying 308 a hermetic overlayer on a top surface of the film; and patterning 310 the film through the overlayer by an EUV exposure to provide a PR pattern. Yet further steps can include stripping 314 the overlayer, thereby providing a photoresist stack having EUV exposed areas and EUV unexposed areas; and developing 316 the film, thereby removing the EUV exposed areas and providing a PR pattern within the film.

Optional steps may be conducted to further treat the substrate, overlayer, and/or film. In one instance, the method can include an optional step 304 of cleaning the backside surface or bevel of the substrate or removing an edge bead of the photoresist that was deposited in the prior step. Such cleaning or removing steps can be useful for removing particles that may be present after depositing a photoresist layer. In another instance, the method can include an optional step 306 of performing a post application bake (PAB) of the deposited photoresist layer, thereby removing residual moisture from the layer to form a film; or pretreating the photoresist layer in any useful manner. In yet another instance, the method can include an optional step 312 of performing a post exposure bake (PEB) of the exposed photoresist layer, thereby further removing residual moisture from the layer or promoting chemical condensation within the film; or post-treating the photoresist layer in any useful manner. In another instance, the method can include an optional step 318 of hardening the EUV unexposed areas (e.g., by using plasma exposure and/or a post development bake (PDB)), thereby providing a photoresist mask. Additional post-application processes are described herein, and any of these processes can be conducted as an optional step for any method described herein.

Any useful type of chemistry can be employed during the depositing, applying, and/or developing steps. Such steps may be based on dry processes employing chemistry in a gaseous phase or wet processes employing chemistry in a wet phase. Various embodiments include combining all dry operations of film formation by vapor deposition, (EUV) lithographic photopatterning, dry stripping, and dry development. Various other embodiments include dry processing operations described herein advantageously combined with wet processing operations, for example, spin-on EUV photoresists (wet process), such as available from Inpria Corp., may be combined with dry development or other wet or dry processes as described herein. In various embodiments, the wafer clean may be a wet process as described herein, while other processes are dry processes. In yet other embodiments, a wet development process may be used.

Furthermore, experimental conditions during depositing, applying, developing, and baking steps can be optimized in any useful manner. In one embodiment, the applying step (of providing a hermetic overlayer) is conducted at a lower temperature than the PAB step. For instance, the applying step can be conducted at a temperature less than about 100° C. or at a temperature of from about 0° C. to about 100° C. or from about 23° C. to about 100° C. In particular embodiments, the PAB step is conducted at a temperature greater than about 100° C. or at a temperature of from about 100° C. to about 200° C. or from about 100° C. to about 250° C.

FIG. 3B-3E provide flow charts of methods involving various combinations of wet and dry processes. FIG. 3B presents an exemplary method 320 for depositing and developing a photoresist (PR) by an all dry development process. In operation 322, a layer of photoresist is deposited as a wet deposition process, such as by providing spin-on film. Next, operation 324 is an optional process to clean the wafer backside and/or bevel.

Operation 326 is an optional PAB that occurs after photoresist deposition and prior to EUV exposure. Operation 326 may involve a combination of thermal treatment, chemical exposure, and moisture to increase the EUV sensitivity of the PR, thereby reducing the EUV dose to develop a pattern in the PR. In some embodiments, when a PAB is employed, the step of applying the hermetic overlayer can possess a lower thermal budget than the baking step

In operation 328, a hermetic overlayer is applied to a top surface of the PR. Such an application can employ any useful deposition process described herein.

In operation 330, the PR is exposed to EUV radiation to develop a pattern. Generally, the EUV exposure causes a change in the chemical composition and cross-linking of the PR, creating a contrast in etch selectivity that can be used to remove a portion of the PR.

Operation 332 is an optional PEB to further increase contrast in etch selectivity of the PR. In one instance, the PR can be thermally treated in the presence of various chemical species to promote reactivity within the EUV exposed portions of the resist upon exposure to a stripping agent (e.g., a halide-based etchant, such as HCl, HBr, H₂, Cl₂, Br₂, BCl₃, or combinations thereof, as well as any halide-based development process described herein).

In operation 334, the hermetic overlayer is stripped, thereby providing access to the EUV exposed areas. Then, in operation 336, the PR pattern is developed. In various embodiments of development, the exposed regions are removed (positive tone) or the unexposed regions are removed (negative tone). In some embodiments, development may include a selective deposition on either the exposed or unexposed regions of the PR, followed by an etching operation. In other embodiments, the stripping step and the developing step are conducted using the same or different process. In yet other embodiments, the stripping step and the developing step are conducted without a vacuum break. In various embodiments, these steps may be dry processes or wet processes.

Operation 318 includes an optional hardening of the EUV unexposed areas (e.g., by using plasma exposure and/or a post development bake (PDB)), thereby providing a photoresist mask.

Each of operations 322-338 is further elucidated herein. In various embodiments, methods of the present technology combine all dry steps of film formation by vapor deposition, (EUV) lithographic photopatterning, and dry development (e.g., as in FIG. 3D). In other embodiments, methods of the present technology include a wet deposition and a dry development (e.g., as in FIG. 3B), or a dry deposition and a wet development (e.g., as in FIG. 3C). In some processes, a substrate may directly go to a dry development/etch chamber (e.g., for stripping the overlayer and/or developing the film) following photopatterning in an EUV scanner. Such processes may avoid material and productivity costs associated with a wet development.

FIG. 3C presents an exemplary method 340 for employing dry deposition of PR and wet development of PR. The method 340 can include dry depositing 342 a layer of PR, optionally cleaning 344 the wafer backside and/or bevel, optionally performing 346 a PAB or a pre-treatment to process the PR layer, applying 348 a hermetic overlayer to a top surface of the PR, exposing 350 the PR to EUV radiation to develop a pattern, optionally performing 352 a PEB or another post-treatment to further increase contrast in etch selectivity of the PR, stripping 354 the hermetic overlayer, wet developing 356 the PR pattern, and optionally hardening 358 the EUV unexposed areas.

FIG. 3D presents another exemplary method 360 for employing dry deposition of PR and dry development of PR. The method 360 can include dry depositing 362 a layer of PR, optionally cleaning 364 the wafer backside and/or bevel, optionally performing 366 a PAB or a pre-treatment to process the PR layer, applying 368 a hermetic overlayer to a top surface of the PR, exposing 370 the PR to EUV radiation to develop a pattern, optionally performing 372 a PEB or another post-treatment to further increase contrast in etch selectivity of the PR, stripping 374 the hermetic overlayer, dry developing 376 the PR pattern, and optionally hardening 378 the EUV unexposed areas.

FIG. 3E presents yet another exemplary method 380 for employing dry deposition, wet post-deposition processing, and dry development. The method 380 can include dry depositing 382 a layer of PR, processing 384 the wafer with a wet metal oxide (MeOx) edge bead removal (EBR) step as well as wafer backside and/or bevel cleaning, optionally performing 386 a PAB or a pre-treatment to process the PR layer, applying 388 a hermetic overlayer to a top surface of the PR, exposing 390 the PR to EUV radiation to develop a pattern, optionally performing 392 a PEB or another post-treatment to further increase contrast in etch selectivity of the PR, stripping 394 the hermetic overlayer, dry developing 396 the PR pattern, and optionally hardening 398 the EUV unexposed areas.

Without limiting the mechanism, function, or utility of the present technology, dry processes of the present technology may provide various benefits relative to wet development processes among those known in the art. For example, dry vapor deposition techniques described herein can be used to deposit thinner and more defect free films than can be applied using spin-coating techniques, in which the exact thickness of the deposited film can be modulated and controlled simply by increasing or decreasing the length of the deposition step or sequence. Accordingly, a dry process may provide more tunability and give further critical dimension (CD) control and scum removal. Dry development can improve performance (e.g., prevent line collapse due to surface tension in wet development) and/or enhance throughput (e.g., by avoiding wet development track). Other advantages may include eliminating the use of organic solvent developers, reducing sensitivity to adhesion issues, avoiding the need to apply and remove wet resist formulations (e.g., avoiding scumming and pattern distortion), improving line edge roughness, patterning directly over device topography, offering the ability to tune hardmask chemistry to the specific substrate and semiconductor device design, and avoiding other solubility-based limitations. Additional details, materials, processes, steps, and apparatuses are described herein.

### EUV-Sensitive Materials

The methods herein can include any useful EUV-sensitive material (e.g., including a photoresist including such EUV-sensitive materials) to provide a film (e.g., an imaging layer or a resist film) and/or a hermetic overlayer. The EUV-sensitive material can be composed or of include a metal (e.g., tin (Sn), tellurium (Te), bismuth (Bi), or antimony (Sb)); a metal oxide, such as tin oxide (e.g., SnO₂), tellurium oxide (e.g., TeO₂), and bismuth oxide (e.g., Bi₂O₃); an alloy, such as tin alloys (e.g., a tin telluride alloy, an antimony telluride (e.g., Sb₂Te₃), a bismuth telluride alloy (e.g., Bi₂Te₃), or a tin bismuth alloy, including an alloy having 60% tin or above); or a combination thereof. In some embodiments, the EUV-sensitive material includes an organometal oxide (e.g., RM(MO)ₙ, in which M is a metal and R is an organic moiety having one or more carbon atoms, such as in alkyl, alkylamino, or alkoxy).

The EUV-sensitive material can be formed by using one or more metal-containing precursors, optionally in the presence of one or more counter-reactants. In particular embodiments, the metal-containing precursor include one or more ligands (e.g., labile ligands) that can be removed or cleaved by EUV radiation. Furthermore, the precursor can be deposited (e.g., using any deposition process described herein) and optionally processed (e.g., baked, treated, annealed, exposed to plasma, etc.) to provide a metal oxide layer (e.g., a layer including a network of metal oxide bonds, which may include other non-metal and non-oxygen groups).

Exemplary metal-containing precursors can include a metal halide, a capping agent, or an organometallic agent. In a precursor, the metal (or M) can be any metal with a high EUV absorption cross-section (e.g., equal to or greater than 1×10⁷ cm²/mol).

The layers herein (e.g., an imaging layer, a resist film, and/or a hermetic overlayer) may include an element (e.g., a metal atom or a non-metal atom) having a high photoabsorption cross-section, such as equal to or greater than 1×10⁷ cm²/mol. Such elements can be provided by depositing one or more precursor(s) to provide the layer.

The layers, either alone or together, can be considered a film. In some embodiments, the film is a radiation-sensitive film (e.g., an EUV-sensitive film). This film, in turn, can serve as an EUV resist, as further described herein. In particular embodiments, the layer or film can include one or more ligands (e.g., EUV labile ligands) that can be removed, cleaved, or crosslinked by radiation (e.g., EUV or DUV radiation).

The precursor can provide a patternable film that is sensitive to radiation (or a patterning radiation-sensitive film or a photopatternable film). Such radiation can include EUV radiation, DUV radiation, or UV radiation that is provided by irradiating through a patterned mask, thereby being a patterned radiation. The film itself can be altered by being exposed to such radiation, such that the film is radiation-sensitive or photosensitive. In particular embodiments, the precursor is an organometallic compound, which includes at least one metal center.

The precursor can have any useful number and type of ligand(s). In some embodiments, the ligand can be characterized by its ability to react in the presence of a counter-reactant or in the presence of patterned radiation. For instance, the precursor can include a ligand that reacts with a counter-reactant, which can introduce linkages between metal centers (e.g., an —O— linkage). In another instance, the precursor can include a ligand that eliminates in the presence of patterned radiation. Such an EUV labile ligand can include branched or linear alkyl groups having a beta-hydrogen, as well as any described herein for R in formula (I) or (II).

The precursor can be any useful metal-containing precursor, such as an organometallic agent, a metal halide, or a capping agent (e.g., as described herein). In a non-limiting instance, the precursor includes a structure having formula (I):

MₐR_{b} (I),

wherein:
M is a metal or an atom having a high EUV absorption cross-section;
each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand;
a≥1; and b≥1.

In another non-limiting instance, the precursor includes a structure having formula (II):

MₐR_{b}L_{c} (II),

wherein:
M is a metal or an atom having a high EUV absorption cross-section;
each R is, independently, halo, optionally substituted alkyl, optionally substituted aryl, optionally substituted amino, optionally substituted alkoxy, or L;
each L is, independently, a ligand, an anionic ligand, a neutral ligand, a multidentate ligand, ion, or other moiety that is reactive with a counter-reactant, in which R and L with M, taken together, can optionally form a heterocyclyl group or in which R and L, taken together, can optionally form a heterocyclyl group;
a≥1; b≥1; and c≥1.

In some embodiments, each ligand within the precursor can be one that is reactive with a counter-reactant. In one instance, the precursor includes a structure having formula (II), in which each R is, independently, L. In another instance, the precursor includes a structure having formula (IIa):

MₐL_{c} (IIa),

wherein:
M is a metal or an atom having a high EUV absorption cross-section;
each L is, independently, a ligand, ion, or other moiety that is reactive with a counter-reactant, in which two L, taken together, can optionally form a heterocyclyl group;
a≥1; and c≥1.
   In particular embodiments of formula (IIa), a is 1. In further embodiments, c is 2, 3, or 4.

For any formula herein, M can be a metal or a metalloid or an atom with a high patterning radiation-absorption cross-section (e.g., an EUV absorption cross-section that is equal to or greater than 1×10⁷ cm²/mol). In some embodiments, M is tin (Sn), bismuth (Bi), tellurium (Te), cesium (Cs), antimony (Sb), indium (In), molybdenum (Mo), hafnium (Hf), iodine (I), zirconium (Zr), iron (Fe), cobalt (Co), nickel (Ni), copper (Cu), zinc (Zn), silver (Ag), platinum (Pt), and lead (Pb). In further embodiments, M is Sn, a is 1, and c is 4 in formula (I), (II), or (IIa). In other embodiments, M is Sn, a is 1, and c is 2 in formula (I), (II), or (IIa). In particular embodiments, M is Sn(II) (e.g., in formula (I), (II), or (IIa)), thereby providing a precursor that is a Sn(II)-based compound. In other embodiments, M is Sn(IV) (e.g., in formula (I), (II), or (IIa)), thereby providing a precursor that is a Sn(IV)-based compound. In particular embodiments, the precursor includes iodine (e.g., as in periodate).

For any formula herein, each R is, independently, H, halo, optionally substituted alkyl, optionally substituted cycloalkyl, optionally substituted cycloalkenyl, optionally substituted alkenyl, optionally substituted alkynyl, optionally substituted alkoxy (e.g., —OR¹, in which R¹ can be optionally substituted alkyl), optionally substituted alkanoyloxy, optionally substituted aryl, optionally substituted amino, optionally substituted bis(trialkylsilyl)amino, optionally substituted trialkylsilyl, oxo, an anionic ligand (e.g., oxido, chlorido, hydrido, acetate, iminodiacetate, propanoate, butanoate, benzoate, etc.), a neutral ligand, or a multidentate ligand.

In some embodiments, the optionally substituted amino is —NR¹R², in which each R¹ and R² is, independently, H or alkyl; or in which R¹ and R², taken together with the nitrogen atom to which each are attached, form a heterocyclyl group, as defined herein. In other embodiments, the optionally substituted bis(trialkylsilyl)amino is —N(SiR¹R²R³)₂, in which each R¹, R², and R³ is, independently, optionally substituted alkyl. In yet other embodiments, the optionally substituted trialkylsilyl is —SiR¹R²R³, in which each R¹, R², and R³ is, independently, optionally substituted alkyl.

In other embodiments, the formula includes a first R (or first L) that is —NR¹R² and a second R (or second L) that is —NR¹R², in which each R¹ and R² is, independently, H or optionally substituted alkyl; or in which R¹ from a first R (or first L) and R¹ from a second R (or second L), taken together with the nitrogen atom and the metal atom to which each are attached, form a heterocyclyl group, as defined herein. In yet other embodiments, the formula includes a first R that is —OR¹ and a second R that is —OR¹, in which each R¹ is, independently, H or optionally substituted alkyl; or in which R¹ from a first R and R¹ from a second R, taken together with the oxygen atom and the metal atom to which each are attached, form a heterocyclyl group, as defined herein.

In some embodiments, at least one of R or L (e.g., in formula (I), (II), or (IIa)) is optionally substituted alkyl. Non-limiting alkyl groups include, e.g., CₙH₂ₙ₊₁, where n is 1, 2, 3, or greater, such as methyl, ethyl, n-propyl, isopropyl, n-butyl, isobutyl, s-butyl, or t-butyl. In various embodiments, R or L has at least one beta-hydrogen or beta-fluorine. In other embodiments, at least one of R or L is a halo-substituted alkyl (e.g., a fluoro-substituted alkyl).

In some embodiments, each R or L or at least one R or L (e.g., in formula (I), (II), or (IIa)) is halo. In particular, the precursor can be a metal halide. Non-limiting metal halides include SnBr₄, SnCl₄, SnI₄, and SbCl₃.

In some embodiments, each R or L or at least one R or L (e.g., in formula (I), (II), or (IIa)) can include a nitrogen atom. In particular embodiments, one or more R or L can be optionally substituted amino, an optionally substituted monoalkylamino (e.g., —NR¹H, in which R¹ is optionally substituted alkyl), an optionally substituted dialkylamino (e.g., —NR¹R², in which each R¹ and R² is, independently, optionally substituted alkyl), or optionally substituted bis(trialkylsilyl)amino. Non-limiting R and L substituents can include, e.g., —NMe₂, —NHMe, —NEt₂, —NHEt, —NMeEt, —N(t-Bu)-[CHCH₃]₂—N(t-Bu)-(tbba), —N(SiMe₃)₂, and —N(SiEt₃)₂.

In some embodiments, each R or L or at least one R or L (e.g., in formula (I), (II), or (IIa)) can include a silicon atom. In particular embodiments, one or more R or L can be optionally substituted trialkylsilyl or optionally substituted bis(trialkylsilyl)amino. Non-limiting R or L substituents can include, e.g., —SiMe₃, —SiEt₃, —N(SiMe₃)₂, and —N(SiEt₃)₂.

In some embodiments, each R or L or at least one R or L (e.g., in formula (I), (II), or (IIa)) can include an oxygen atom. In particular embodiments, one or more R or L can be optionally substituted alkoxy or optionally substituted alkanoyloxy. Non-limiting R or L substituents include, e.g., methoxy, ethoxy, isopropoxy (i-PrO), t-butoxy (t-BuO), acetate (—OC(O)—CH₃), and —O═C(CH₃)—CH═C(CH₃)—O— (acac).

Any formulas herein can include one or more neutral ligands. Non-limiting neutral ligands include an optionally substituted amine (e.g., NR₃ or R₂N-Ak-NR₂, in which each R can be, independently, H, optionally substituted alkyl, optionally substituted hydrocarbyl, or optionally substituted aryl, and Ak is optionally substituted alkylene), an optionally substituted phosphine (e.g., PR₃ or R₂P-Ak-PR₂, in which each R can be, independently, H, optionally substituted alkyl, optionally substituted hydrocarbyl, or optionally substituted aryl, and Ak is optionally substituted alkylene), an optionally substituted ether (e.g., OR₂, in which each R can be, independently, H, optionally substituted alkyl, optionally substituted hydrocarbyl, or optionally substituted aryl), an optionally substituted alkyl, an optionally substituted alkene, an optionally substituted alkyne, an optionally substituted benzene, oxo, or carbon monoxide.

Any formulas herein can include one or more multidentate (e.g., bidentate) ligands.

Non-limiting multidentate ligand include a diketonate (e.g., acetylacetonate (acac) or —OC(R¹)-Ak-(R¹)CO— or —OC(R¹)—C(R²)—(R¹)CO—), a bidentate chelating dinitrogen (e.g., —N(R¹)-Ak-N(R¹)— or —N(R³)—CR⁴—CR²═N(R¹)—), an aromatic (e.g., —Ar—), an amidinate (e.g., —N(R¹)—C(R²)—N(R¹)—), an aminoalkoxide (e.g., —N(R¹)-Ak-O— or —N(R¹)₂-Ak-O—), a diazadienyl (e.g., —N(R¹)—C(R²)—C(R²)—N(R¹)—), a cyclopentadienyl, a pyrazolate, an optionally substituted heterocyclyl, an optionally substituted alkylene, or an optionally substituted heteroalkylene. In particular embodiments, each R¹ is, independently, H, optionally substituted alkyl, optionally substituted haloalkyl, or optionally substituted aryl; each R² is, independently, H or optionally substituted alkyl; R³ and R⁴, taken together, forms an optionally substituted heterocyclyl; Ak is optionally substituted alkylene; and Ar is optionally substituted arylene.

In particular embodiments, the precursor includes tin. In some embodiments, the tin precursor includes SnR or SnR₂ or SnR₄ or R₃SnSnR₃, wherein each R is, independently, H, halo, optionally substituted C₁₋₁₂ alkyl, optionally substituted C₁₋₁₂ alkoxy, optionally substituted amino (e.g., —NR¹R²), optionally substituted C₂₋₁₂ alkenyl, optionally substituted C₂₋₁₂ alkynyl, optionally substituted C₃₋₈ cycloalkyl, optionally substituted aryl, cyclopentadienyl, optionally substituted bis(trialkylsilyl)amino (e.g., —N(SiR¹R²R³)₂), optionally substituted alkanoyloxy (e.g., acetate), a diketonate (e.g., —OC(R¹)-Ak-(R²)CO—), or a bidentate chelating dinitrogen (e.g., —N(R¹)-Ak-N(R¹)—). In particular embodiments, each R¹, R², and R³ is, independently, H or C₁₋₁₂ alkyl (e.g., methyl, ethyl, isopropyl, t-butyl, or neopentyl); and Ak is optionally substituted C₁₋₆ alkylene. In particular embodiments, each R is, independently, halo, optionally substituted C₁₋₁₂ alkoxy, optionally substituted amino, optionally substituted aryl, cyclopentadienyl, or a diketonate. Non-limiting tin precursors include SnF₂, SnH₄, SnBr₄, SnCl₄, SnI₄, tetramethyl tin (SnMe₄), tetraethyl tin (SnEt₄), trimethyl tin chloride (SnMe₃Cl), dimethyl tin dichloride (SnMe₂Cl₂), methyl tin trichloride (SnMeCl₃), tetraallyltin, tetravinyl tin, hexaphenyl ditin (IV) (Ph₃Sn—SnPh₃, in which Ph is phenyl), dibutyldiphenyltin (SnBu₂Ph₂), trimethyl(phenyl) tin (SnMe₃Ph), trimethyl(phenylethynyl) tin, tricyclohexyl tin hydride, tributyl tin hydride (SnBu₃H), dibutyltin diacetate (SnBu₂(CH₃COO)₂), tin(II) acetylacetonate (Sn(acac)₂), SnBu₃(OEt), SnBu₂(OMe)₂, SnBu₃(OMe), Sn(t-BuO)₄, Sn(n-Bu)(t-BuO)₃, tetrakis(dimethylamino)tin (Sn(NMe₂)₄), tetrakis(ethylmethylamino)tin (Sn(NMeEt)₄), tetrakis(diethylamino)tin(IV) (Sn(NEt₂)₄), (dimethylamino)trimethyl tin(IV) (Sn(Me)₃(NMe₂), Sn(i-Pr)(NMe₂)₃, Sn(n-Bu)(NMe₂)₃, Sn(s-Bu)(NMe₂)₃, Sn(i-Bu)(NMe₂)₃, Sn(t-Bu)(NMe₂)₃, Sn(t-Bu)₂(NMe₂)₂, Sn(t-Bu)(NEt₂)₃, Sn(tbba), Sn(II) (1,3-bis(1,1-dimethylethyl)-4,5-dimethyl-(4R,5R)-1,3,2-diazastannolidin-2-ylidene), or bis[bis(trimethylsilyl)amino] tin (Sn[N(SiMe₃)₂]₂).

In other embodiments, the precursor includes bismuth, such as in BiR₃, wherein each R is, independently, halo, optionally substituted C₁₋₁₂ alkyl, mono-C₁₋₁₂ alkylamino (e.g., —NR¹H), di-C₁₋₁₂ alkylamino (e.g., —NR¹R²), optionally substituted aryl, optionally substituted bis(trialkylsilyl)amino (e.g., —N(SiR¹R²R³)₂), or a diketonate (e.g., —OC(R⁴)-Ak-(R⁵)CO—). In particular embodiments, each R¹, R², and R³ is, independently, C₁₋₁₂ alkyl (e.g., methyl, ethyl, isopropyl, t-butyl, or neopentyl); and each R⁴ and R⁵ is, independently, H or optionally substituted C₁₋₁₂ alkyl (e.g., methyl, ethyl, isopropyl, t-butyl, or neopentyl). Non-limiting bismuth precursors include BiCl₃, BiMe₃, BiPh₃, Bi(NMe₂)₃, Bi[N(SiMe₃)₂]₃, and Bi(thd)₃, in which thd is 2,2,6,6-tetramethyl-3,5-heptanedionate.

In other embodiments, the precursor includes tellurium, such as TeR₂ or TeR₄, wherein each R is, independently, halo, optionally substituted C₁₋₁₂ alkyl (e.g., methyl, ethyl, isopropyl, t-butyl, and neopentyl), optionally substituted C₁₋₁₂ alkoxy, optionally substituted aryl, hydroxyl, oxo, or optionally substituted trialkylsilyl. Non-limiting tellurium precursors include dimethyl tellurium (TeMe₂), diethyl tellurium (TeEt₂), di(n-butyl) tellurium (Te(n-Bu)₂), di(isopropyl) tellurium (Te(i-Pr)₂), di(t-butyl) tellurium (Te(t-Bu)₂), t-butyl tellurium hydride (Te(t-Bu)(H)), Te(OEt)₄, bis(trimethylsilyl)tellurium (Te(SiMe₃)₂), and bis(triethylsilyl) tellurium (Te(SiEt₃)₂).

Yet other precursors and non-limiting substituents are described herein. For instance, precursors can be any having a structure of formulas (I), (II), and (IIa), as described above; or formulas (III), (IV), (V), (VI), (VII), or (VIII), as described below. Any of the substituents M, R, X, or L, as described herein, can be employed in any of formulas (I), (II), (IIa), (III), (IV), (V), (VI), (VII), or (VIII).

A non-limiting precursor includes a metal halide having the following formula (III):

MXₙ (III),

in which M is a metal, X is halo, and n is 2 to 4, depending on the selection of M. Exemplary metals for M include Sn, Te, Bi, or Sb. Exemplary metal halides include SnBr₄, SnCl₄, SnI₄, and SbCl₃.

Another non-limiting precursor includes a structure having formula (IV):

MRₙ (IV),

in which M is a metal; each R is independently H, an optionally substituted alkyl, amino (e.g., —NR₂, in which each R is independently alkyl), optionally substituted bis(trialkylsilyl)amido (e.g., —N(SiR₃), in which each R is independently alkyl), or an optionally substituted trialkylsilyl (e.g., —SiR₃, in which each R is independently alkyl); and n is 2 to 4, depending on the selection of M. Exemplary metals for M include Sn, Te, Bi, or Sb. The alkyl group may be CₙH₂ₙ₊₁, where n is 1, 2, 3, or greater. Exemplary organometallic agents include SnMe₄, SnEt₄, TeRₙ, RTeR, t-butyl tellurium hydride (Te(t-Bu)(H)), dimethyl tellurium (TeMe₂), di(t-butyl) tellurium (Te(t-Bu)₂), di(isopropyl)tellurium (Te(i-Pr)₂), bis(trimethylsilyl)tellurium (Te(SiMe₃)₂), bis(triethylsilyl) tellurium (Te(SiEt₃)₂), tris(bis(trimethylsilyl)amido) bismuth (Bi[N(SiMe₃)₂]₃), Sb(NMe₂)₃, and the like.

Another non-limiting precursor can include a capping agent having the following formula (V):

MLₙ (V),

in which M is a metal; each L is independently an optionally substituted alkyl, amino (e.g., —NR¹R², in which each of R¹ and R² can be H or alkyl, such as any described herein), alkoxy (e.g., —OR, in which R is alkyl, such as any described herein), halo, or other organic substituent; and n is 2 to 4, depending on the selection of M. Exemplary metals for M include Sn, Te, Bi, or Sb. Exemplary ligands include dialkylamino (e.g., dimethylamino, methylethylamino, and diethylamino), alkoxy (e.g., t-butoxy and isopropoxy), halo (e.g., F, Cl, Br, and I), or other organic substituents (e.g., acetylacetone or N²,N³-di-tertbutyl-butane-2,3-diamino). Non-limiting capping agents include SnCl₄; SnI₄; Sn(NR₂)₄, wherein each of R is independently methyl or ethyl; or Sn(t-BuO)₄. In some embodiments, multiple types of ligands are present.

A precursor can include a hydrocarbyl-substituted capping agent having the following formula (VI):

RₙMXₘ (VI),

wherein M is a metal, R is a C₂₋₁₀ alkyl or substituted alkyl having a beta-hydrogen, and X is a suitable leaving group upon reaction with a hydroxyl group of the exposed hydroxyl groups. In various embodiments, n=1 to 3, and m=4−n, 3−n, or 2−n, so long as m>0 (or m≥1). For example, R may be t-butyl, t-pentyl, t-hexyl, cyclohexyl, isopropyl, isobutyl, sec-butyl, n-butyl, n-pentyl, n-hexyl, or derivatives thereof having a heteroatom substituent in the beta position. Suitable heteroatoms include halogen (F, Cl, Br, or I), or oxygen (—OH or —OR). X may be dialkylamino (e.g., dimethylamino, methylethylamino, or diethylamino), alkoxy (e.g., t-butoxy, isopropoxy), halo (e.g., F, Cl, Br, or I), or another organic ligand. Examples of hydrocarbyl-substituted capping agents include t-butyltris(dimethylamino)tin (Sn(t-Bu)(NMe₂)₃), n-butyltris(dimethylamino)tin (Sn(n-Bu)(NMe₂)₃), t-butyltris(diethylamino)tin (Sn(t-Bu)(NEt₂)₃), di(t-butyl)di(dimethylamino)tin (Sn(t-Bu)₂(NMe₂)₂), sec-butyltris(dimethylamino)tin (Sn(s-Bu)(NMe₂)₃), n-pentyltris(dimethylamino)tin (Sn(n-pentyl)(NMe₂)₃), i-butyltris(dimethylamino) tin (Sn(i-Bu)(NMe₂)₃), i-propyltris(dimethylamino)tin (Sn(i-Pr)(NMe₂)₃), t-butyltris(t-butoxy)tin (Sn(t-Bu)(t-BuO)₃), n-butyl(tris(t-butoxy)tin (Sn(n-Bu)(t-BuO)₃), or isopropyltris(t-butoxy)tin (Sn(i-Pr)(t-BuO)₃).

In various embodiments, a precursor includes at least one alkyl group on each metal atom that can survive the vapor-phase reaction, while other ligands or ions coordinated to the metal atom can be replaced by the counter-reactants. Accordingly, another non-limiting precursor includes an organometallic agent having the formula (VII):

MₐR_{b}L_{c} (VII),

in which M is a metal; R is an optionally substituted alkyl; L is a ligand, ion, or other moiety which is reactive with the counter-reactant; a≥1; b≥1; and c≥1. In particular embodiments, a=1, and b+c=4. In some embodiments, M is Sn, Te, Bi, or Sb. In particular embodiments, each L is independently amino (e.g., —NR¹R², in which each of R¹ and R² can be H or alkyl, such as any described herein), alkoxy (e.g., —OR, in which R is alkyl, such as any described herein), or halo (e.g., F, Cl, Br, or I). Exemplary agents include SnMe₃Cl, SnMe₂Cl₂, SnMeCl₃, SnMe(NMe₂)₃, SnMe₂(NMe₂)₂, SnMe₃(NMe₂), and the like.

In other embodiments, the non-limiting precursor includes an organometallic agent having the formula (VIII):

MₐL_{c} (VIII),

in which M is a metal; L is a ligand, ion, or other moiety which is reactive with the counter-reactant; a≥1; and c≥1. In particular embodiments, c=n−1, and n is 2, 3, or 4. In some embodiments, M is Sn, Te, Bi, or Sb. Counter-reactants preferably have the ability to replace the reactive moieties ligands or ions (e.g., L in formulas herein) so as to link at least two metal atoms via chemical bonding.

In any embodiment herein, R can be an optionally substituted alkyl (e.g., C₁₋₁₀ alkyl). In one embodiment, alkyl is substituted with one or more halo (e.g., halo-substituted C₁₋₁₀ alkyl, including one, two, three, four, or more halo, such as F, Cl, Br, or I). Exemplary R substituents include CₙH₂ₙ₊₁, preferably wherein n≥3; and CₙFₓH₍₂ₙ₊₁₋ₓ₎, wherein 2n+1≤x≤1. In various embodiments, R has at least one beta-hydrogen or beta-fluorine. For example, R may be selected from the group consisting of i-propyl, n-propyl, t-butyl, i-butyl, n-butyl, sec-butyl, n-pentyl, i-pentyl, t-pentyl, sec-pentyl, and mixtures thereof.

In any embodiment herein, L may be any moiety readily displaced by a counter-reactant to generate an M-OH moiety, such as a moiety selected from the group consisting of an amino (e.g., —NR¹R², in which each of R¹ and R² can be H or alkyl, such as any described herein), alkoxy (e.g., —OR, in which R is alkyl, such as any described herein), carboxylates, halo (e.g., F, Cl, Br, or I), and mixtures thereof.

Exemplary organometallic agents include SnMeCl₃, (N²,N³-di-t-butyl-butane-2,3-diamido) tin(II) (Sn(tbba)), bis(bis(trimethylsilyl)amido) tin(II), tetrakis(dimethylamino) tin(IV) (Sn(NMe₂)₄), t-butyl tris(dimethylamino) tin (Sn(t-butyl)(NMe₂)₃), i-butyl tris(dimethylamino) tin (Sn(i-Bu)(NMe₂)₃), n-butyl tris(dimethylamino) tin (Sn(n-Bu)(NMe₂)₃), sec-butyl tris(dimethylamino) tin (Sn(s-Bu)(NMe₂)₃), i-propyl(tris)dimethylamino tin (Sn(i-Pr)(NMe₂)₃), n-propyl tris(diethylamino) tin (Sn(n-Pr)(NEt₂)₃), and analogous alkyl(tris)(t-butoxy) tin compounds, such as t-butyl tris(t-butoxy) tin (Sn(t-Bu)(t-BuO)₃). In some embodiments, the organometallic agents are partially fluorinated.

Such precursors can be employed alone to form an EUV-sensitive material or can be used in combination with one or more counter-reactants. Counter-reactants preferably have the ability to replace the reactive moieties ligands or ions (e.g., L in formulas herein) so as to link at least two metal atoms via chemical bonding. Exemplary counter-reactants include oxygen-containing counter-reactants, such as O₂, O₃, water, peroxides (e.g., hydrogen peroxide), oxygen plasma, water plasma, alcohols, dihydroxy alcohols, polyhydroxy alcohols, fluorinated dihydroxy alcohol, fluorinated polyhydroxy alcohols, fluorinated glycols, formic acid, and other sources of hydroxyl moieties, as well as combinations thereof. In various embodiments, a counter-reactant reacts with the precursor by forming oxygen bridges between neighboring metal atoms. Other potential counter-reactants include hydrogen sulfide and hydrogen disulfide, which can crosslink metal atoms via sulfur bridges and bis(trimethylsilyl)tellurium, which can crosslink metal atoms via tellurium bridges. In addition, hydrogen iodide may be utilized to incorporate iodine into the film.

Furthermore, two or more different precursors can be employed within each layer (e.g., film or overlayer). For instance, two or more of any metal-containing precursors herein can be employed to form an alloy. In one non-limiting instance, tin telluride can be formed by employing tin precursor including an NR₂ ligand with RTeH, RTeD, or R₂Te precursors, in which R is an alkyl, particularly t-butyl or i-propyl. In another instance, a metal telluride can be formed by using a first metal precursor including an alkoxy or a halo ligand (e.g., SbCl₃) with a tellurium-containing precursor including a trialkylsilyl ligand (e.g., bis(trimethylsilyl)tellurium).

Yet other exemplary EUV-sensitive materials, as well as processing methods and apparatuses, are described in U.S. Pat. No. 9,996,004; Int. Pat. Pub. No. WO 2020/102085; and Int. Pat. Pub. No. WO 2019/217749, each of which is incorporated herein by reference in its entirety.

### Lithographic Processes

EUV lithography makes use of EUV resists, which may be polymer-based chemically amplified resists produced by liquid-based spin-on techniques or metal oxide-based resists produced by dry vapor-deposited techniques. Lithographic methods can include patterning the resist, e.g., by exposure of the EUV resist with EUV radiation to form a photo pattern, followed by developing the pattern by removing a portion of the resist according to the photo pattern to form the mask.

It should also be understood that the while present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. Such methods include those where a substrate (e.g., optionally having exposed hydroxyl groups) is contacted with a metal-containing precursor (e.g., any described herein) to form a metal oxide (e.g., a layer including a network of metal oxide bonds, which may include other non-metal and non-oxygen groups) film as the imaging/PR layer on the surface of the substrate. The specific methods may depend on the particular materials and applications used in the semiconductor substrate and ultimate semiconducting device. Thus, the methods described in this application are merely exemplary of the methods and materials that may be used in present technology.

Directly photopatternable EUV resists may be composed of or contain metals and/or metal oxides mixed within organic components. The metals/metal oxides are highly promising in that they can enhance the EUV photon adsorption and generate secondary electrons and/or show increased etch selectivity to an underlying film stack and device layers. To date, these resists have been developed using a wet (solvent) approach, which requires the wafer to move to the track, where it is exposed to developing solvent, dried and baked. Wet development does not only limit productivity but can also lead to line collapse due to surface tension effects during the evaporation of solvent between fine features.

Dry development techniques have been proposed to overcome these issues by eliminating substrate delamination and interface failures. Dry development has its own challenges, including etch selectivity between unexposed and EUV exposed resist material which can lead to a higher dose to size requirement for effective resist exposure when compared to wet development. Suboptimal selectivity can also cause PR corner rounding due to longer exposures under etching gas, which may increase line CD variation in the following transfer etch step. Additional processes employed during lithography are described in detail below.

### Deposition Processes, Including Dry Deposition

As discussed above, the present disclosure provides methods for making imaging layers on semiconductor substrates, which may be patterned using EUV or other next generation lithographic techniques. Methods include those where polymerized organometallic materials are produced in a vapor and deposited on a substrate. In some embodiments, dry deposition can employ any useful metal-containing precursor (e.g., metal halides, capping agents, or organometallic agents described herein). In other embodiments, a spin-on formulation may be used. Deposition processes can include applying a EUV-sensitive material as a resist film and/or as a hermetic overlayer upon the resist film. Exemplary EUV-sensitive materials are described herein.

The present technology includes methods by which EUV-sensitive thin films are deposited on a substrate, such films being operable as resists for subsequent EUV lithography and processing. Furthermore, a secondary EUV-sensitive film can be deposited upon an underlying primary EUV-sensitive film. In one instance, the secondary film constitutes a hermetic overlayer, and the primary film constitutes the imaging layer.

Such EUV-sensitive films comprise materials which, upon exposure to EUV, undergo changes, such as the loss of bulky pendant ligands bonded to metal atoms in low density M-OH rich materials, allowing their crosslinking to denser M-O-M bonded metal oxide materials. Through EUV patterning, areas of the film are created that have altered physical or chemical properties relative to unexposed areas. These properties may be exploited in subsequent processing, such as to dissolve either unexposed or exposed areas, or to selectively deposit materials on either the exposed or unexposed areas. In some embodiments, the unexposed film has a hydrophobic surface, and the exposed film has a hydrophilic surface (it being recognized that the hydrophilic properties of exposed and unexposed areas are relative to one another) under the conditions at which such subsequent processing is performed. For example, the removal of material may be performed by leveraging differences in chemical composition, density and cross-linking of the film. Removal may be by wet processing or dry processing, as further described herein.

The thickness of the EUV-patternable film formed on the surface of the substrate may vary according to the surface characteristics, materials used, and processing conditions. In various embodiments, the film thickness may range from about 0.5 nm to about 100 nm. Preferably, the film has a sufficient thickness to absorb most of the EUV light under the conditions of EUV patterning. For example, the overall absorption of the resist film may be 30% or less (e.g., 10% or less, or 5% or less), so that the resist material at the bottom of the resist film is sufficiently exposed. In some embodiments, the film thickness is from 10 nm to 20 nm. Without limiting the mechanism, function, or utility of the present disclosure, it is believed that, unlike wet, spin-coating processes of the art, the processes of the present disclosure have fewer restrictions on the surface adhesion properties of the substrate, and therefore can be applied to a wide variety of substrates. Moreover, as discussed above, the deposited films may closely conform to surface features, providing advantages in forming masks over substrates, such as substrates having underlying features, without “filling in” or otherwise planarizing such features.

The film (e.g., imaging layer) or hermetic overlayer may be composed of a metal oxide layer deposited in any useful manner. Such a metal oxide layer can be deposited or applied by using any EUV-sensitive material described herein, such as a metal-containing precursor (e.g., a metal halide, a capping agent, or an organometallic agent). In exemplary processes, a polymerized organometallic material is formed in vapor phase or in situ on the surface of the substrate in order to provide the metal oxide layer. The metal oxide layer may be employed as the film, the hermetic overlayer, or as an adhesion layer (e.g., between the substrate and the film; or between the film and the overlayer).

Optionally, the metal oxide layer can include a hydroxyl-terminated metal oxide layer, which can be deposited by employing a capping agent (e.g., any described herein) with an oxygen-containing counter-reactant. Such a hydroxyl-terminated metal oxide layer can be employed, e.g., as an adhesion layer between two other layers, such as between the substrate and the film and/or between the film and the overlayer.

Exemplary deposition techniques (e.g., for a film or a hermetic overlayer) include any described herein, such as ALD (e.g., thermal ALD and plasma-enhanced ALD), spin-coat deposition, PVD including PVD co-sputtering, CVD (e.g., PE-CVD or LP-CVD), sputter deposition, e-beam deposition including e-beam co-evaporation, etc., or a combination thereof, such as ALD with a CVD component, such as a discontinuous, ALD-like process in which metal-containing precursors and counter-reactants are separated in either time or space.

In general, depositing can include mixing a vapor stream of a metal-containing precursor (e.g., any described herein, such as a metal halide, a capping agent, or an organometallic agent) with a vapor stream of a counter-reactant and depositing the organometallic material onto the surface of the semiconductor substrate. In some embodiments, mixing the metal-containing precursor with the counter-reactant forms a polymerized organometallic material. As will be understood by one of ordinary skill in the art, the mixing and depositing aspects of the process may be concurrent, in a substantially continuous process.

In some embodiments, the deposition is ALD, in a cyclical process of depositing a metal-containing precursor (e.g., any described herein, such as a metal halide, a capping agent, or an organometallic agent) and depositing a counter-reactant (e.g., an oxygen-containing counter-reactant). Materials and processes among those useful herein for depositing metal oxide layers are described in Nazarov D V et al., “Atomic layer deposition of tin dioxide nanofilms: a review,” 40 Rev. Adv. Mater. Sci. 262-275 (2015).

In an exemplary continuous CVD process, two or more gas streams, in separate inlet paths, of a metal-containing precursor (e.g., any described herein, such as a metal halide, a capping agent, or an organometallic agent) and source of counter-reactant are introduced to the deposition chamber of a CVD apparatus, where they mix and react in the gas phase, to form a film on the substrate. The streams may be introduced, for example, using a dual plenum showerhead. The apparatus is configured so that the streams of metal-containing precursor and counter-reactant are mixed in the chamber, allowing the agent and the counter-reactant to react to form a film (e.g., a metal oxide coating or agglomerated polymeric materials, such as via metal-oxygen-metal bond formation).

For depositing metal oxide, the CVD process is generally conducted at reduced pressures, such as from 0.1 Torr to 10 Torr. In some embodiments, the process is conducted at pressures from 1 Torr to 2 Torr. The temperature of the substrate is preferably below the temperature of the reactant streams. For example, the substrate temperature may be from 0° C. to 250° C., or from ambient temperature (e.g., 23° C.) to 150° C.

For depositing agglomerated polymeric materials, the CVD process is generally conducted at reduced pressures, such as from 10 mTorr to 10 Torr. In some embodiments, the process is conducted at from 0.5 to 2 Torr. The temperature of the substrate is preferably at or below the temperature of the reactant streams. For example, the substrate temperature may be from 0° C. to 250° C., or from ambient temperature (e.g., 23° C.) to 150° C. In various processes, deposition of the polymerized organometallic material on the substrate occurs at rates inversely proportional to surface temperature. Without limiting the mechanism, function, or utility of present technology, it is believed that the product from such vapor-phase reaction becomes heavier in molecular weight as metal atoms are crosslinked by counter-reactants, and then the product is then condensed or otherwise deposited onto the substrate. In various embodiments, the steric hindrance of the bulky alkyl groups prevents the formation of densely packed network and produces porous, low density films.

A potential advantage of using dry deposition methods is ease of tuning the composition of the film as it grows. In a CVD process, this may be accomplished by changing the relative flows of the two or more metal-containing precursors during deposition. Deposition may occur between 30° C. and 200° C. at pressures between 0.01 Torr to 100 Torr, but more generally between about 0.1 Torr and 10 Torr.

A film (e.g., a metal oxide coating or agglomerated polymeric materials, such as via metal-oxygen-metal bond formation) may also be deposited by an ALD process. For example, the metal-containing precursor and counter-reactant are introduced at separate times, representing an ALD cycle. The precursors react on the surface, forming up to a monolayer of material at a time for each cycle. This may allow for excellent control over the uniformity of film thickness across the surface. The ALD process is generally conducted at reduced pressures, such as from 0.1 Torr to 10 Torr. In some embodiments, the process is conducted from 1 Torr to 2 Torr. The substrate temperature may be from 0° C. to 250° C., or from ambient temperature (e.g., 23° C.) to 150° C. The process may be a thermal process or, preferably, a plasma-assisted deposition.

Any of the deposition methods herein can be modified to allow for use of two or more different metal-containing precursors. In one embodiment, the precursors can include the same metal but different ligands. In another embodiment, the precursors can include different metal groups. In one non-limiting instance, alternating flows of various volatile metal-containing precursors can provide a mixed metal layer, such as use of a metal alkoxide precursor having a first metal (e.g., Sn) with a silyl-based precursor having a different second metal (e.g., Te).

Furthermore, any of the deposition methods herein can be modified to provide one or more layers within a film or a hermetic overlayer. In one instance, different precursors can be employed in each layer. In another instance, the same precursor may be employed for each layer, but the top-most layer can be treated (e.g., by using plasma to remove one or more ligands within the deposited layer) to provide a different chemical composition (e.g., a different density of metal-ligand bonds).

Deposition processes can be employed on any useful surface. As referred to herein, the “surface” is a surface onto which a film of the present technology is to be deposited or that is to be exposed to EUV during processing. Such a surface can be present on a substrate (e.g., upon which a film is to be deposited), on a film (e.g., upon which a hermetic overlayer is to be deposited), or on a hermetic overlayer (e.g., upon which reactions can be conducted to promote etching within the EUV exposed areas).

Any useful substrate can be employed, including any material construct suitable for lithographic processing, particularly for the production of integrated circuits and other semiconducting devices. In some embodiments, substrates are silicon wafers. Substrates may be silicon wafers upon which features have been created (“underlying topographical features”), having an irregular surface topography.

Such underlying topographical features may include regions in which material has been removed (e.g., by etching) or regions in which materials have been added (e.g., by deposition) during processing prior to conducting a method of this technology. Such prior processing may include methods of this technology or other processing methods in an iterative process by which two or more layers of features are formed on the substrate. Without limiting the mechanism, function, or utility of the present technology, it is believed that, in some embodiments, methods of the present technology offer advantages relative to methods among those known in the art in which photolithographic films are deposited on the surface of substrates using spin casting methods. Such advantages may derive from the conformance of the films of the present technology to underlying features without “filling in” or otherwise planarizing such features, and the ability to deposit films on a wide variety of material surfaces.

In some embodiments, an incoming wafer can be prepared with a substrate surface of a desired material, with the uppermost material being the layer into which the resist pattern is transferred. While the material selection may vary depending on integration, it is generally desired to select a material that can be etched with high selectivity to (i.e., much faster than) the EUV resist or imaging layer. Suitable substrate materials can include various carbon-based films (e.g., ashable hard mask (AHM)), silicon-based films (e.g., silicon, silicon oxide, silicon nitride, silicon oxynitride, or silicon oxycarbonitride, as well as doped forms thereof, including SiOₓ, SiOₓN_{y}, SiOₓC_{y}N_{z}, a-Si:H, poly-Si, or SiN), or any other (generally sacrificial) film applied to facilitate the patterning process.

In some embodiments, the substrate is a hard mask, which is used in lithographic etching of an underlying semiconductor material. The hard mask may comprise any of a variety of materials, including amorphous carbon (a-C), SnOₓ, SiO₂, SiOₓN_{y}, SiOₓC, Si₃N₄, TiO₂, TiN, W, W-doped C, WOₓ, HfO₂, ZrO₂, and Al₂O₃. For example, the substrate may preferably comprise SnOₓ, such as SnO₂. In various embodiments, the layer may be from 1 nm to 100 nm thick, or from 2 nm to 10 nm thick.

In some non-limiting embodiments, a substrate comprises an underlayer. An underlayer may be deposited on a hard mask or other layer and is generally underneath an imaging layer (or film), as described herein. An underlayer may be used to improve the sensitivity of a PR, increase EUV absorptivity, and/or increase the patterning performance of the PR. In cases where there are device features present on the substrate to be patterned which create significant topography, another important function of the underlayer can be to overcoat and planarize the existing topography so that the subsequent patterning step may be performed on a flat surface with all areas of the pattern in focus. For such applications, the underlayer (or at least one of multiple underlayers) may be applied using spin-coating techniques. When the PR material being employed possesses a significant inorganic component, for example it exhibits a predominately metal oxide framework, the underlayer may advantageously be a carbon-based film, applied either by spin-coating or by dry vacuum-based deposition processes. The layer may include various ashable hard mask (AHM) films with carbon- and hydrogen-based compositions and may be doped with additional elements, such as tungsten, boron, nitrogen, or fluorine.

In some embodiments, a surface activation operation may be used to activate the surface (e.g., of the substrate and/or a film) for future operations. For example, for a SiOₓ surface, a water or oxygen/hydrogen plasma may be used to create hydroxyl groups on the surface. For a carbon- or hydrocarbon-based surface, various treatment (e.g., a water, hydrogen/oxygen, CO₂ plasma, or ozone treatment) may be used to create carboxylic acids/or hydroxyl groups. Such approaches can prove critical for improving the adhesion of resist features to the substrate, which might otherwise delaminate or lift off during handling or within the solvent during development.

Adhesion may also be enhanced by inducing roughness in the surface to increase the surface area available for interaction, as well as directly improve mechanical adhesion. For example, first a sputtering process using Ar or other non-reactive ion bombardment can be used to produce rough surfaces. Then, the surface can be terminated with a desired surface functionality as described above (e.g., hydroxyl and/or carboxylic acid groups). On carbon, a combination approach can be employed, in which a chemically reactive oxygen-containing plasma such as CO₂, O₂, or H₂O (or mixtures of H₂ and O₂) can be used to etch away a thin layer of film with local non-uniformity and simultaneously terminate with —OH, —OOH, or —COOH groups. This may be done with or without bias. In conjunction with the surface modification strategies mentioned above, this approach could serve the dual purpose of surface roughening and chemical activation of the substrate surface, either for direct adhesion to an inorganic metal-oxide based resist or as an intermediate surface modification for further functionalization.

In various embodiments, the surface (e.g., of the substrate and/or the film) comprises exposed hydroxyl groups on its surface. In general, the surface may be any surface that comprises, or has been treated to produce, an exposed hydroxyl surface. Such hydroxyl groups may be formed on the surface by surface treatment of a substrate using oxygen plasma, water plasma, or ozone. In other embodiments, the surface of the film can be treated to provide exposed hydroxyl groups, upon which a hermetic overlayer can be applied. In various embodiments, the hydroxyl-terminated metal oxide layer has a thickness of from 0.1 nm to 20 nm, or from 0.2 nm to 10 nm, or from 0.5 nm to 5 nm.

### EUV Exposure Processes

EUV exposure of the film can provide EUV exposed areas having activated reactive centers including a metal atom (M), which are produced by EUV-mediated cleavage events. Such reactive centers can include dangling metal bonds, M-H groups, cleaved M-ligand groups, or dimerized M-M bonds.

In particular embodiments, upon EUV exposure, the ligands of the modified interface can undergo a β-hydride elimination, resulting in the formation of M-H bonds at the interface. At this stage, or during the post exposure bake, the M-H bonds may react with the resist to form M-O-M bridges across the interface, effectively increasing the adhesion of the film in the exposed region. To avoid the formation of M-O-M bridges, a hermetic overlayer can be employed.

EUV exposure can have a wavelength in the range of about 10 nm to about 20 nm in a vacuum ambient, such as a wavelength of from 10 nm to 15 nm, e.g., 13.5 nm. In particular, patterning can provide EUV exposed areas and EUV unexposed areas to form a pattern.

The present technology can include patterning using EUV, as well as DUV or e-beam. In such patterning, the radiation is focused on one or more regions of the imaging layer. The exposure is typically performed such that imaging layer film comprises one or more regions that are not exposed to the radiation. The resulting imaging layer may comprise a plurality of exposed and unexposed regions, creating a pattern consistent with the creation of transistor or other features of a semiconductor device, formed by addition or removal of material from the substrate in subsequent processing of the substrate. EUV, DUV and e-beam radiation methods and equipment among useful herein include methods and equipment known in the art.

In some EUV lithography techniques, an organic hardmask (e.g., an ashable hardmask of PECVD amorphous hydrogenated carbon) is patterned using a conventional photoresist process. During photoresist exposure, EUV radiation is absorbed in the resist and in the substrate below, producing highly energetic photoelectrons (e.g., about 100 eV) and in turn a cascade of low-energy secondary electrons (e.g., about 10 eV) that diffuse laterally by several nanometers. These electrons increase the extent of chemical reactions in the resist which increases its EUV dose sensitivity. However, a secondary electron pattern that is random in nature is superimposed on the optical image. This unwanted secondary electron exposure results in loss of resolution, observable line edge roughness (LER) and linewidth variation in the patterned resist. These defects are replicated in the material to be patterned during subsequent pattern transfer etching.

Unlike an insulator such as photoresist, a metal is less susceptible to secondary electron exposure effects since the secondary electrons can quickly lose energy and thermalize by scattering with conduction electrons. Suitable metal elements for this process may include but are not limited to aluminum, silver, palladium, platinum, rhodium, ruthenium, iridium, cobalt, ruthenium, manganese, nickel, copper, hafnium, tantalum, tungsten, gallium, germanium, tin, antimony, or any combination thereof. However, electron scattering in the photoresist used to pattern a blanket metal film into a mask would still lead to unacceptable effects such as LER.

A vacuum-integrated metal hardmask process and related vacuum-integrated hardware that combines film formation (deposition/condensation) and optical lithography with the result of greatly improved EUV lithography (EUVL) performance—e.g., reduced line edge roughness—is disclosed herein.

In various embodiments described herein, a deposition (e.g., condensation) process (e.g., ALD or MOCVD carried out in a PECVD tool, such as the Lam Vector®) can be used to form a thin film of a metal-containing film, such a photosensitive metal salt or metal-containing organic compound (organometallic compound), with a strong absorption in the EUV (e.g., at wavelengths on the order of 10 nm to 20 nm), for example at the wavelength of the EUVL light source (e.g., 13.5 nm=91.8 eV). This film photo-decomposes upon EUV exposure and forms a metal mask that is the pattern transfer layer during subsequent etching (e.g., in a conductor etch tool, such as the Lam 2300® Kiyo®).

Following deposition, the EUV-patternable thin film is patterned by exposure to a beam of EUV light, typically under relatively high vacuum. For EUV exposure, the metal-containing film can then be deposited in a chamber integrated with a lithography platform (e.g., a wafer stepper such as the TWINSCAN NXE: 3300B® platform supplied by ASML of Veldhoven, NL) and transferred under vacuum so as not to react before exposure. Integration with the lithography tool is facilitated by the fact that EUVL also requires a greatly reduced pressure given the strong optical absorption of the incident photons by ambient gases such as H₂O, O₂, etc. In other embodiments, the photosensitive metal film deposition and EUV exposure may be conducted in the same chamber.

### Development Processes, Including Dry Development

EUV exposed areas and hermetic overlayers can be removed by any useful development process. In one embodiment, the EUV exposed area can have activated reactive centers, such as dangling metal bonds, M-H groups, or dimerized M-M bonds. In particular embodiments, M-H groups can be selectively removed by employing one or more dry development processes (e.g., halide chemistry). In other embodiments, M-M bonds can be selectively removed by employing a wet development process, e.g., use of hot ethanol and water to provide soluble M(OH)ₙ groups.

Dry development processes can include use of halides, such as HCl- or HBr-based processes. While this disclosure is not limited to any particular theory or mechanism of operation, the approach is understood to leverage the chemical reactivity of the dry-deposited EUV photoresist films with the clean chemistry (e.g., HCl, HBr, and BCl₃) to form volatile products using vapors or plasma. The dry-deposited EUV photoresist films can be removed with etch rates of up to 1 nm/s. The quick removal of dry-deposited EUV photoresist films by these chemistries is applicable to chamber cleaning, backside clean, bevel clean, overlayer stripping, and PR developing. Although the films can be removed using vapors at various temperatures (e.g., HCl or HBr at a temperature greater than −10° C., or BCl₃ at a temperature greater than 80° C., for example), a plasma can also be used to further accelerate or enhance the reactivity.

Plasma processes include transformer coupled plasma (TCP), inductively coupled plasma (ICP) or capacitively coupled plasma (CCP), employing equipment and techniques among those known in the art. For example, a process may be conducted at a pressure of >0.5 mTorr (e.g., such as from 1 mTorr to 100 mTorr), at a power level of <1000 W (e.g., <500 W). Temperatures may be from 30° C. to 300° C. (e.g., 30° C. to 120° C.), at flow rate of 100 to 1000 standard cubic centimeters per minute (sccm), e.g., about 500 sccm, for from 1 to 3000 seconds (e.g., 10 seconds to 600 seconds).

Where the halide reactant flows are of hydrogen gas and halide gas, a remote plasma/UV radiation is used to generate radicals from the H₂ and Cl₂ and/or Br₂, and the hydrogen and halide radicals are flowed to the reaction chamber to contact the patterned EUV photoresist on the substrate layer of the wafer. Suitable plasma power may range from 100 W to 500 W, with no bias. It should be understood that while these conditions are suitable for some processing reactors, e.g., a Kiyo etch tool available from Lam Research Corporation, Fremont, Calif., a wider range of process conditions may be used according to the capabilities of the processing reactor.

In thermal development processes, the substrate is exposed to dry development chemistry (e.g., a Lewis Acid) in a vacuum chamber (e.g., oven). Suitable chambers can include a vacuum line, a dry development hydrogen halide chemistry gas (e.g., HBr, HCl) line, and heaters for temperature control. In some embodiments, the chamber interior can be coated with corrosion resistant films, such as organic polymers or inorganic coatings. One such coating is polytetrafluoroethylene ((PTFE), e.g., Teflon 1M). Such materials can be used in thermal processes of this disclosure without risk of removal by plasma exposure.

The process conditions for the dry development may be reactant flow of 100 sccm to 500 sccm (e.g., 500 sccm HBr or HCl), temperature of −10° C. to 120° C. (e.g., −10° C.), pressure of 1 mTorr to 500 mTorr (e.g., 300 mTorr) with no plasma and for a time of about 10 sec to 1 min, dependent on the photoresist film and hermetic overlayer and their composition and properties.

In various embodiments, methods of the present disclosure combine all dry steps of film and overlayer, formation by vapor deposition, (EUV) lithographic photopatterning, overlayer stripping, and dry development. In such processes, a substrate may directly go to a dry development/etch chamber following photopatterning in an EUV scanner. Such processes may avoid material and productivity costs associated with a wet development. A dry process can also provide more tunability and give further CD control and/or scum removal.

In various embodiments, the EUV photoresist, containing some amount of metal, metal oxide and organic components, can be dry developed by a thermal, plasma (e.g., including possibly photoactivated plasma, such as lamp-heated or UV lamp heated), or a mixture of thermal and plasma methods while flowing a dry development gas including a compound of formula RxZy, where R=B, Al, Si, C, S, SO with x>0 and Z=Cl, H, Br, F, CH₄ and y>0. The dry development can result in a positive tone, in which the RxZy species selectively removes the exposed material, leaving behind the unexposed counterpart as a mask. In some embodiments, the exposed portions of organotin oxide-based photoresist films are removed by dry development in accordance with this disclosure. Positive tone dry development may be achieved by the selective dry development (removal) of EUV exposed regions exposed to flows comprising hydrogen halides or hydrogen and halides, including HCl and/or HBr without striking a plasma, or flows of H₂ and Cl₂ and/or Br₂ with a remote plasma or UV radiation generated from plasma to generate radicals.

### Post-Application Processes

The methods herein can include any useful post-application processes, as described below.

For the backside and bevel clean process, the vapor and/or the plasma can be limited to a specific region of the wafer to ensure that only the backside and the bevel are removed, without any film degradation on the frontside of the wafer. The dry-deposited EUV photoresist films being removed are generally composed of Sn, O and C, but the same clean approaches can be extended to films of other metal oxide resists and materials. In addition, this approach can also be used for film strip and PR rework.

Suitable process conditions for a dry bevel edge and backside clean may be a reactant flow of 100 sccm to 500 sccm (e.g., 500 sccm HCl, HBr, or H₂ and Cl₂ or Br₂, BCl₃ or H₂), temperature of −10° C. to 120° C. (e.g., 20° C.), pressure of 20 mTorr to 500 mTorr (e.g., 300 mTorr), plasma power of 0 to 500 W at high frequency (e.g., 13.56 MHz), and for a time of about 10 sec to 20 sec, dependent on the photoresist film and composition and properties. It should be understood that while these conditions are suitable for some processing reactors, e.g., a Kiyo etch tool available from Lam Research Corporation, Fremont, Calif., a wider range of process conditions may be used according to the capabilities of the processing reactor.

Photolithography processes typically involve one or more bake steps, to facilitate the chemical reactions required to produce chemical contrast between exposed and unexposed areas of the photoresist. For high volume manufacturing (HVM), such bake steps are typically performed on tracks where the wafers are baked on a hot-plate at a pre-set temperature under ambient air or in some cases N₂ flow. More careful control of the bake ambient as well as introduction of additional reactive gas component in the ambient during these bake steps can help further reduce the dose requirement and/or improve pattern fidelity.

According to various aspects of this disclosure, one or more post treatments to metal and/or metal oxide-based photoresists after deposition (e.g., post-application bake (PAB)) and/or exposure (e.g., post-exposure bake (PEB)) and/or development (e.g., post-development bake (PDB)) are capable of increasing material property differences between exposed and unexposed photoresist and therefore decreasing dose to size (DtS), improving PR profile, and improving line edge and width roughness (LER/LWR) after subsequent dry development. Such processing can involve a thermal process with the control of temperature, gas ambient, and moisture, resulting in improved dry development performance in processing to follow. In some instances, a remote plasma might be used.

In the case of post-application processing (e.g., PAB), a thermal process with control of temperature, gas ambient (e.g., air, H₂O, CO₂, CO, O₂, O₃, CH₄, CH₃OH, N₂, H₂, NH₃, N₂O, NO, Ar, He, or their mixtures) or under vacuum, and moisture can be used after deposition and before exposure to change the composition of unexposed metal and/or metal oxide photoresist. The change can increase the EUV sensitivity of the material and thus lower dose to size and edge roughness can be achieved after exposure and dry development.

In the case of post-exposure processing (e.g., PEB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum, and moisture can be used to change the composition of both unexposed and exposed photoresist. The change can increase the composition/material properties difference between the unexposed and exposed photoresist and the etch rate difference of dry development etch gas between the unexposed and exposed photoresist. A higher etch selectivity can thereby be achieved. Due to the improved selectivity, a squarer PR profile can be obtained with improved surface roughness, and/or less photoresist residual/scum.

In the case of post-development processing (e.g., post development bake or PDB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum (e.g., with UV), and moisture can be used to change the composition of the unexposed photoresist. In particular embodiments, the condition also includes use of plasma (e.g., including O₂, O₃, Ar, He, or their mixtures). The change can increase the hardness of material, which can be beneficial if the film will be used as a resist mask when etching the underlying substrate.

In these cases, in alternative implementations, the thermal process could be replaced by a remote plasma process to increase reactive species to lower the energy barrier for the reaction and increase productivity. Remote plasma can generate more reactive radicals and therefore lower the reaction temperature/time for the treatment, leading to increased productivity.

Accordingly, one or multiple processes may be applied to modify the photoresist itself to increase dry development selectivity. This thermal or radical modification can increase the contrast between unexposed and exposed material and thus increase the selectivity of the subsequent dry development step. The resulting difference between the material properties of unexposed and exposed material can be tuned by adjusting process conditions including temperature, gas flow, moisture, pressure, and/or RF power. The large process latitude enabled by dry development, which is not limited by material solubility in a wet developer solvent, allows more aggressive conditions to be applied further enhancing the material contrast that can be achieved. The resulting high material contrast feeds back a wider process window for dry development and thus enables increased productivity, lower cost, and better defectivity performance.

A substantial limitation of wet-developed resist films is limited temperature bakes. Since wet development relies on material solubility, heating to or beyond 220° C., for example, can greatly increase the degree of cross-linking in both exposed and unexposed regions of a metal-containing PR film such that both become insoluble in the wet development solvents, so that the film can no longer by reliably wet developed. For dry-developed resist films, in which the etch rate difference (i.e., selectivity) between the exposed and unexposed regions of the PR is relied upon for removal of just the exposed or unexposed portion of the resist, the treatment temperature in a PAB, PEB, or PDB can be varied across a much broader window to tune and optimize the treatment process, for example from about 90° C. to 250° C., such as 90° C. to 190° C., for PAB, and about 170° C. to 250° C. or more, such as 190° C. to 240° C., for PEB and/or PDB. Decreasing etch rate and greater etch selectivity has been found to occur with higher treatment temperatures in the noted ranges.

In particular embodiments, the PAB, PEB, and/or PDB treatments may be conducted with gas ambient flow in the range of 100 sccm to 10000 sccm, moisture content in the amount of a few percent up to 100% (e.g., 20%-50%), at a pressure between atmospheric and vacuum, and for a duration of about 1 to 15 minutes, for example about 2 minutes.

These findings can be used to tune the treatment conditions to tailor or optimize processing for particular materials and circumstances. For example, the selectivity achieved for a given EUV dose with a 220° C. to 250° C. PEB thermal treatment in air at about 20% humidity for about 2 minutes can be made similar to that for about a 30% higher EUV dose with no such thermal treatment. So, depending on the selectivity requirements/constraints of the semiconductor processing operation, a thermal treatment such as described herein can be used to lower the EUV dose needed. Or, if higher selectivity is required and higher dose can be tolerated, much higher selectivity, up to 100 times exposed vs. unexposed, can be obtained than would be possible in a wet development context.

Yet other steps can include in situ metrology, in which physical and structural characteristics (e.g., critical dimension, film thickness, etc.) can be assessed during the photolithography process. In one embodiment, such in situ metrology occurs after stripping the hermetic overlayer. Modules to implement in situ metrology include, e.g., scatterometry, ellipsometry, downstream mass spectroscopy, and/or plasma enhanced downstream optical emission spectroscopy modules.

### Apparatuses

The present disclosure also includes any apparatus configured to perform any methods described herein. In one embodiment, the apparatus for depositing a hermetic overlayer includes a deposition module comprising a chamber for depositing an EUV-sensitive material as a film; an application module comprising a chamber for applying a hermetic overlayer; a patterning module comprising an EUV photolithography tool with a source of sub-30 nm wavelength radiation; and a development module comprising a chamber for stripping the overlayer and developing the film.

The apparatus can further include a controller having instructions for such modules. In one embodiment, the controller includes one or more memory devices, one or more processors, and system control software coded with instructions for conducting overlayer deposition. Such includes can include for, in the deposition module, depositing the film on a top surface of a substrate; in the application module, applying the overlayer on a top surface of the film; in the patterning module, patterning the film through the overlayer with sub-30 nm resolution directly by EUV exposure, thereby forming a pattern through the overlayer and within the film; and in the development module, stripping the overlayer and developing the film. In particular embodiments, the development module provides for removal of the EUV exposed areas, thereby providing a pattern within the film.

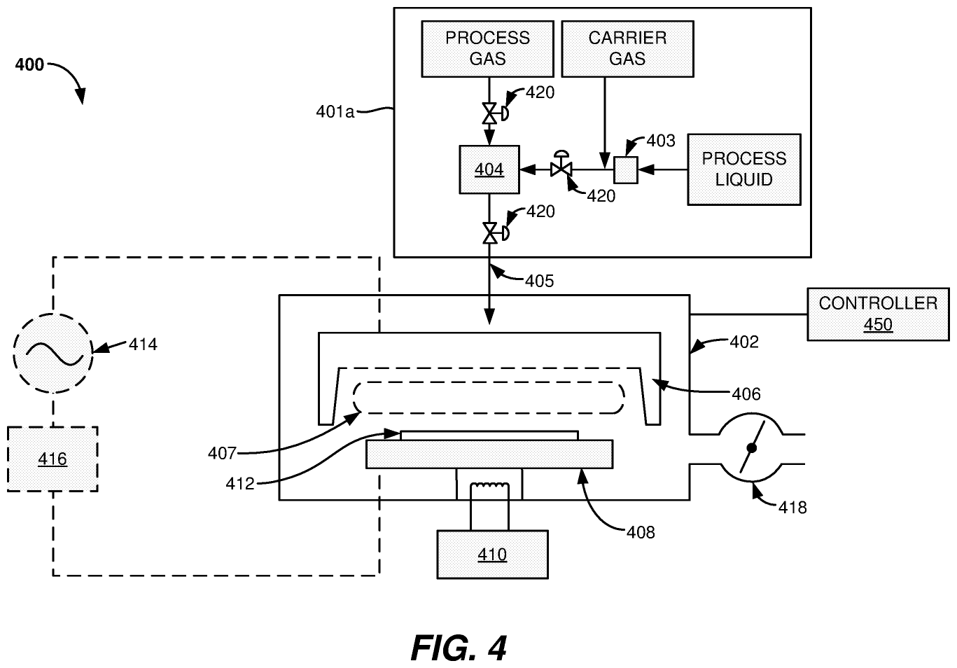

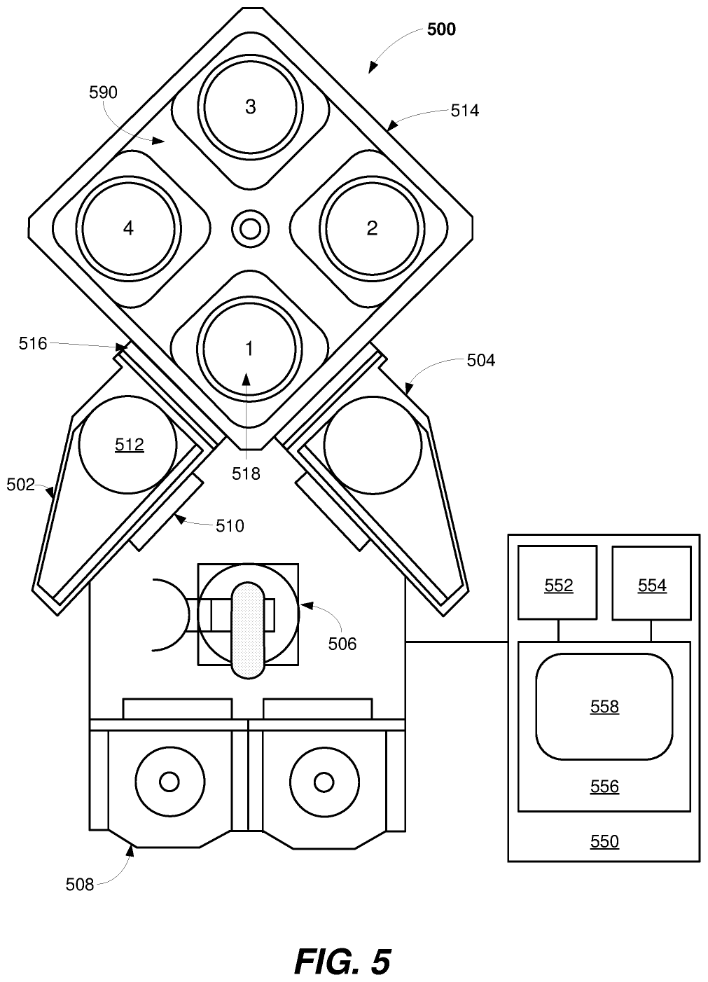

FIG. 4 depicts a schematic illustration of an embodiment of process station 400 having a process chamber body 402 for maintaining a low pressure environment that is suitable for implementation of described dry stripping and development embodiments. A plurality of process stations 400 may be included in a common low pressure process tool environment. For example, FIG. 5 depicts an embodiment of a multi-station processing tool 500, such as a VECTOR® processing tool available from Lam Research Corporation, Fremont, Calif. In some embodiments, one or more hardware parameters of the process station 400 including those discussed in detail below may be adjusted programmatically by one or more computer controllers 450.

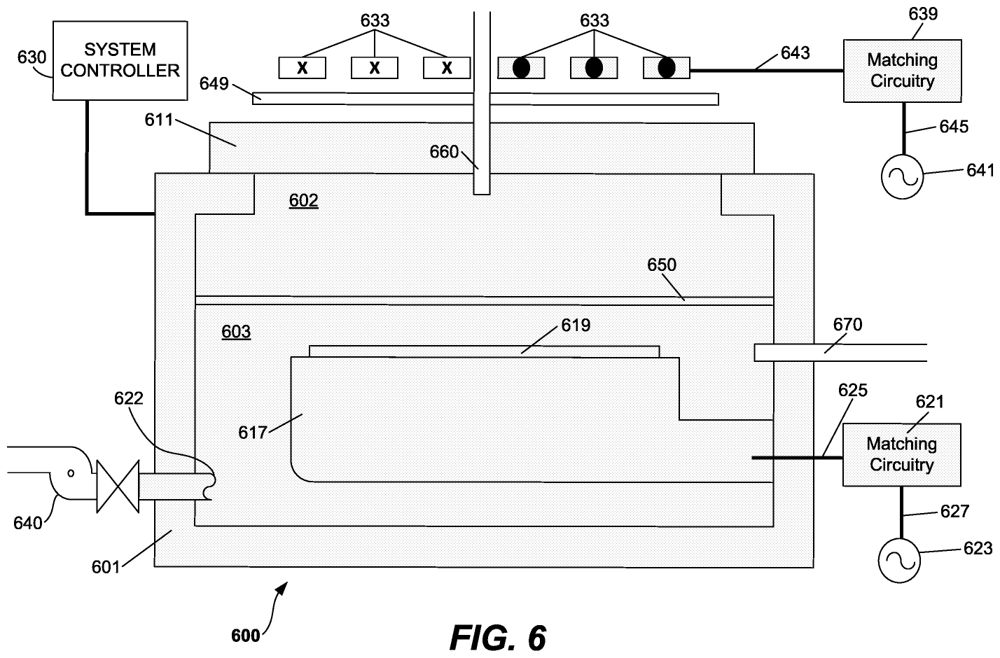

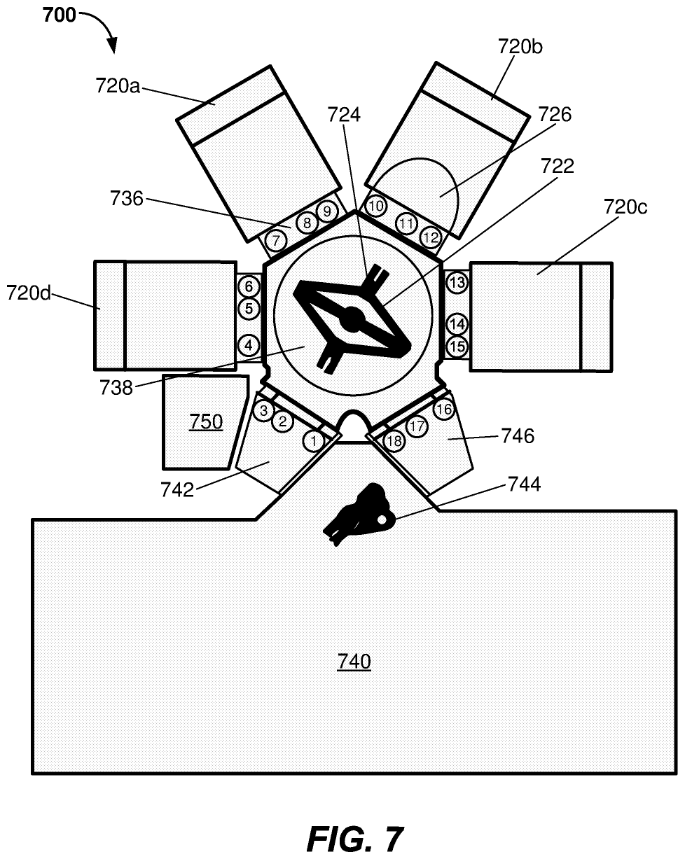

A process station may be configured as a module in a cluster tool. FIG. 7 depicts a semiconductor process cluster tool architecture with vacuum-integrated deposition and patterning modules suitable for implementation of the embodiments described herein. Such a cluster process tool architecture can include resist deposition, resist exposure (EUV scanner), resist dry development and etch modules, as described herein with reference to FIG. 6 and FIG. 7.

In some embodiments, certain of the processing functions can be performed consecutively in the same module, for example dry development and etch. And embodiments of this disclosure are directed to methods and apparatus for receiving a wafer, including a photopatterned EUV resist thin film layer disposed on a layer or layer stack to be etched, to a dry development/etch chamber following photopatterning in an EUV scanner; dry developing photopatterned EUV resist thin film layer; and then etching the underlying layer using the patterned EUV resist as a mask, as described herein.

Returning to FIG. 4, process station 400 fluidly communicates with reactant delivery system 401a for delivering process gases to a distribution showerhead 406 by a connection 405. Reactant delivery system 401a optionally includes a mixing vessel 404 for blending and/or conditioning process gases, for delivery to showerhead 406. One or more mixing vessel inlet valves 420 may control introduction of process gases to mixing vessel 404. Where plasma exposure is used, plasma may also be delivered to the showerhead 406 or may be generated in the process station 400.

FIG. 4 includes an optional vaporization point 403 for vaporizing liquid reactant to be supplied to the mixing vessel 404. In some embodiments, a liquid flow controller (LFC) upstream of vaporization point 403 may be provided for controlling a mass flow of liquid for vaporization and delivery to process station 400. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 406 distributes process gases toward substrate 412. In the embodiment shown in FIG. 4, the substrate 412 is located beneath showerhead 406 and is shown resting on a pedestal 408. Showerhead 406 may have any suitable shape and may have any suitable number and arrangement of ports for distributing process gases to substrate 412.

In some embodiments, pedestal 408 may be raised or lowered to expose substrate 412 to a volume between the substrate 412 and the showerhead 406. It will be appreciated that, in some embodiments, pedestal height may be adjusted programmatically by a suitable computer controller 450.

In some embodiments, pedestal 408 may be temperature controlled via heater 410. In some embodiments, the pedestal 408 may be heated to a temperature of greater than 0° C. and up to 300° C. or more, for example 50° C. to 120° C., such as about 65° C. to 80° C., during non-plasma thermal exposure of a photopatterned resist to dry development chemistry, such as HBr, HCl, or BCl₃, as described in disclosed embodiments.

Further, in some embodiments, pressure control for process station 400 may be provided by a butterfly valve 418. As shown in the embodiment of FIG. 4, butterfly valve 418 throttles a vacuum provided by a downstream vacuum pump (not shown). However, in some embodiments, pressure control of process station 400 may also be adjusted by varying a flow rate of one or more gases introduced to the process station 400.

In some embodiments, a position of showerhead 406 may be adjusted relative to pedestal 408 to vary a volume between the substrate 412 and the showerhead 406. Further, it will be appreciated that a vertical position of pedestal 408 and/or showerhead 406 may be varied by any suitable mechanism within the scope of the present disclosure. In some embodiments, pedestal 408 may include a rotational axis for rotating an orientation of substrate 412. It will be appreciated that, in some embodiments, one or more of these example adjustments may be performed programmatically by one or more suitable computer controllers 450.

Where plasma may be used, for example in gentle plasma-based dry development embodiments and/or etch operations conducted in the same chamber, showerhead 406 and pedestal 408 electrically communicate with a radio frequency (RF) power supply 414 and matching network 416 for powering a plasma 407. In some embodiments, the plasma energy may be controlled by controlling one or more of a process station pressure, a gas concentration, an RF source power, an RF source frequency, and a plasma power pulse timing. For example, RF power supply 414 and matching network 416 may be operated at any suitable power to form a plasma having a desired composition of radical species. Examples of suitable powers are up to about 500 W.

In some embodiments, instructions for a controller 450 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a recipe phase may include instructions for setting a flow rate of a dry development chemistry reactant gas, such as HBr or HCl, and time delay instructions for the recipe phase. In some embodiments, the controller 450 may include any of the features described below with respect to system controller 550 of FIG. 5.

As described above, one or more process stations may be included in a multi station processing tool. FIG. 5 shows a schematic view of an embodiment of a multi station processing tool 500 with an inbound load lock 502 and an outbound load lock 504, either or both of which may include a remote plasma source. A robot 506 at atmospheric pressure is configured to move wafers from a cassette loaded through a pod 508 into inbound load lock 502 via an atmospheric port 510. A wafer is placed by the robot 506 on a pedestal 512 in the inbound load lock 502, the atmospheric port 510 is closed, and the load lock is pumped down. Where the inbound load lock 502 includes a remote plasma source, the wafer may be exposed to a remote plasma treatment to treat the silicon nitride surface in the load lock prior to being introduced into a processing chamber 514. Further, the wafer also may be heated in the inbound load lock 502 as well, for example, to remove moisture and adsorbed gases. Next, a chamber transport port 516 to processing chamber 514 is opened, and another robot (not shown) places the wafer into the reactor on a pedestal of a first station shown in the reactor for processing. While the embodiment depicted in FIG. 5 includes load locks, it will be appreciated that, in some embodiments, direct entry of a wafer into a process station may be provided.

The depicted processing chamber 514 includes four process stations, numbered from 1 to 4 in the embodiment shown in FIG. 5. Each station has a heated pedestal (shown at 518 for station 1), and gas line inlets. It will be appreciated that in some embodiments, each process station may have different or multiple purposes. For example, in some embodiments, a process station may be switchable between dry development and etch process modes. Additionally or alternatively, in some embodiments, processing chamber 514 may include one or more matched pairs of dry development and etch process stations. While the depicted processing chamber 514 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 5 depicts an embodiment of a wafer handling system 590 for transferring wafers within processing chamber 514. In some embodiments, wafer handling system 590 may transfer wafers between various process stations and/or between a process station and a load lock. It will be appreciated that any suitable wafer handling system may be employed. Non limiting examples include wafer carousels and wafer handling robots. FIG. 5 also depicts an embodiment of a system controller 550 employed to control process conditions and hardware states of process tool 500. System controller 550 may include one or more memory devices 556, one or more mass storage devices 554, and one or more processors 552. Processor 552 may include a CPU or computer, analog, and/or digital input/output connections, stepper motor controller boards, etc.

In some embodiments, system controller 550 controls all of the activities of process tool 500. System controller 550 executes system control software 558 stored in mass storage device 554, loaded into memory device 556, and executed on processor 552. Alternatively, the control logic may be hard coded in the controller 550. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 558 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 500. System control software 558 may be configured in any suitable way. For example, various process tool component subroutines or control objects may be written to control operation of the process tool components used to carry out various process tool processes. System control software 558 may be coded in any suitable computer readable programming language.

In some embodiments, system control software 558 may include input/output control (IOC) sequencing instructions for controlling the various parameters described above. Other computer software and/or programs stored on mass storage device 554 and/or memory device 556 associated with system controller 550 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 518 and to control the spacing between the substrate and other parts of process tool 500.

A process gas control program may include code for controlling various gas compositions (e.g., HBr or HCl gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 550. The user interface may include a display screen, graphical software displays of the apparatus and/or process conditions, and user input devices such as pointing devices, keyboards, touch screens, microphones, etc.

In some embodiments, parameters adjusted by system controller 550 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 550 from various process tool sensors. The signals for controlling the process may be output on the analog and digital output connections of process tool 500. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 550 may provide program instructions for implementing the above-described deposition processes. The program instructions may control a variety of process parameters, such as DC power level, RF bias power level, pressure, temperature, etc. The instructions may control the parameters to operate dry development and/or etch processes according to various embodiments described herein.

The system controller 550 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 550.

In some implementations, the system controller 550 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 550, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 550 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 550 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 550, in some implementations, may be a part of or coupled to a computer that is integrated with, coupled to the system, otherwise networked to the system, or a combination thereof. For example, the system controller 550 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the system controller 550 receives instructions in the form of data, which specify parameters for each of the processing steps to be performed during one or more operations. It should be understood that the parameters may be specific to the type of process to be performed and the type of tool that the system controller 550 is configured to interface with or control. Thus, as described above, the system controller 550 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the system controller 550 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

FIG. 6 schematically shows a cross-sectional view of an inductively coupled plasma apparatus 600 appropriate for implementing certain embodiments or aspects of embodiments such as dry development and/or etch, an example of which is a Kiyo® reactor, produced by Lam Research Corp. of Fremont, Calif. In other embodiments, other tools or tool types having the functionality to conduct the dry development and/or etch processes described herein may be used for implementation.

The inductively coupled plasma apparatus 600 includes an overall process chamber structurally defined by chamber walls 601 and a window 611. The chamber walls 601 may be fabricated from stainless steel or aluminum. The window 611 may be fabricated from quartz or other dielectric material. An optional internal plasma grid 650 divides the overall process chamber into an upper sub-chamber 602 and a lower sub-chamber 603. In most embodiments, plasma grid 650 may be removed, thereby utilizing a chamber space made of sub-chambers 602 and 603. A chuck 617 is positioned within the lower sub-chamber 603 near the bottom inner surface. The chuck 617 is configured to receive and hold a semiconductor wafer 619 upon which the etching and deposition processes are performed. The chuck 617 can be an electrostatic chuck for supporting the wafer 619 when present. In some embodiments, an edge ring (not shown) surrounds the chuck 617 and has an upper surface that is approximately planar with a top surface of the wafer 619, when present over the chuck 617. The chuck 617 also includes electrostatic electrodes for chucking and dechucking the wafer 619. A filter and DC clamp power supply (not shown) may be provided for this purpose.

Other control systems for lifting the wafer 619 off the chuck 617 can also be provided. The chuck 617 can be electrically charged using an RF power supply 623. The RF power supply 623 is connected to matching circuitry 621 through a connection 627. The matching circuitry 621 is connected to the chuck 617 through a connection 625. In this manner, the RF power supply 623 is connected to the chuck 617. In various embodiments, a bias power of the electrostatic chuck may be set at about 50 V or may be set at a different bias power depending on the process performed in accordance with disclosed embodiments. For example, the bias power may be between about 20 V and about 100 V, or between about 30 V and about 150 V.

Elements for plasma generation include a coil 633 positioned above window 611. In some embodiments, a coil is not used in disclosed embodiments. The coil 633 is fabricated from an electrically conductive material and includes at least one complete turn. The example of a coil 633 shown in FIG. 6 includes three turns. The cross sections of coil 633 are shown with symbols, and coils having an “X” extend rotationally into the page, while coils having a “e” extend rotationally out of the page. Elements for plasma generation also include an RF power supply 641 configured to supply RF power to the coil 633. In general, the RF power supply 641 is connected to matching circuitry 639 through a connection 645. The matching circuitry 639 is connected to the coil 633 through a connection 643. In this manner, the RF power supply 641 is connected to the coil 633. An optional Faraday shield 649 is positioned between the coil 633 and the window 611. The Faraday shield 649 may be maintained in a spaced apart relationship relative to the coil 633. In some embodiments, the Faraday shield 649 is disposed immediately above the window 611. In some embodiments, a Faraday shield is between the window 611 and the chuck 617. In some embodiments, the Faraday shield is not maintained in a spaced apart relationship relative to the coil 633. For example, a Faraday shield may be directly below the window without a gap. The coil 633, the Faraday shield 649, and the window 611 are each configured to be substantially parallel to one another. The Faraday shield 649 may prevent metal or other species from depositing on the window 611 of the process chamber.

Process gases may be flowed into the process chamber through one or more main gas flow inlets 660 positioned in the upper sub-chamber 602 and/or through one or more side gas flow inlets 670. Likewise, though not explicitly shown, similar gas flow inlets may be used to supply process gases to a capacitively coupled plasma processing chamber. A vacuum pump, e.g., a one or two stage mechanical dry pump and/or turbomolecular pump 640, may be used to draw process gases out of the process chamber and to maintain a pressure within the process chamber. For example, the vacuum pump may be used to evacuate the lower sub-chamber 603 during a purge operation of ALD. A valve-controlled conduit may be used to fluidically connect the vacuum pump to the process chamber so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 600, one or more process gases may be supplied through the gas flow inlets 660 and/or 670. In certain embodiments, process gas may be supplied only through the main gas flow inlet 660, or only through the side gas flow inlet 670. In some cases, the gas flow inlets shown in the figure may be replaced by more complex gas flow inlets, one or more showerheads, for example. The Faraday shield 649 and/or optional grid 650 may include internal channels and holes that allow delivery of process gases to the process chamber. Either or both of Faraday shield 649 and optional grid 650 may serve as a showerhead for delivery of process gases. In some embodiments, a liquid vaporization and delivery system may be situated upstream of the process chamber, such that once a liquid reactant or precursor is vaporized, the vaporized reactant or precursor is introduced into the process chamber via a gas flow inlet 660 and/or 670.

Radio frequency power is supplied from the RF power supply 641 to the coil 633 to cause an RF current to flow through the coil 633. The RF current flowing through the coil 633 generates an electromagnetic field about the coil 633. The electromagnetic field generates an inductive current within the upper sub-chamber 602. The physical and chemical interactions of various generated ions and radicals with the wafer 619 etch features of and selectively deposit layers on the wafer 619.

If the plasma grid 650 is used such that there is both an upper sub-chamber 602 and a lower sub-chamber 603, the inductive current acts on the gas present in the upper sub-chamber 602 to generate an electron-ion plasma in the upper sub-chamber 602. The optional internal plasma grid 650 limits the amount of hot electrons in the lower sub-chamber 603. In some embodiments, the apparatus 600 is designed and operated such that the plasma present in the lower sub-chamber 603 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 603 through port 622. The chuck 617 disclosed herein may operate at elevated temperatures ranging between about 10° C. and about 250° C. The temperature will depend on the process operation and specific recipe.

Apparatus 600 may be coupled to facilities (not shown) when installed in a clean room or a fabrication facility. Facilities include plumbing that provide processing gases, vacuum, temperature control, and environmental particle control. These facilities are coupled to apparatus 600, when installed in the target fabrication facility. Additionally, apparatus 600 may be coupled to a transfer chamber that allows robotics to transfer semiconductor wafers into and out of apparatus 600 using typical automation.

In some embodiments, a system controller 630 (which may include one or more physical or logical controllers) controls some or all of the operations of a process chamber. The system controller 630 may include one or more memory devices and one or more processors. In some embodiments, the apparatus 600 includes a switching system for controlling flow rates and durations when disclosed embodiments are performed. In some embodiments, the apparatus 600 may have a switching time of up to about 600 ms, or up to about 750 ms. Switching time may depend on the flow chemistry, recipe chosen, reactor architecture, and other factors.

In some implementations, the system controller 630 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 630, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 630 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 630, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the system controller 630 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 630 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL). The EUVL patterning tool may be a standalone device from which the substrate is moved into and out of for deposition and etching as described herein. Or, as described below, the EUVL patterning tool may be a module on a larger multi-component tool. FIG. 7 depicts a semiconductor process cluster tool architecture with vacuum-integrated deposition, EUV patterning and dry development/etch modules that interface with a vacuum transfer module, suitable for implementation of the processes described herein. While the processes may be conducted without such vacuum integrated apparatus, such apparatus may be advantageous in some implementations.

FIG. 7 depicts a semiconductor process cluster tool architecture 700 with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 738 interfaces with four processing modules 720a-720d, which may be individually optimized to perform various fabrication processes. By way of example, processing modules 720a-720d may be implemented to perform deposition, evaporation, ELD, dry development, etch, strip, and/or other semiconductor processes. For example, module 720a may be an ALD reactor that may be operated to perform in a non-plasma, thermal atomic layer depositions as described herein, such as a Vector tool, available from Lam Research Corporation, Fremont, Calif. And module 720b may be a PECVD tool, such as the Lam Vector®. It should be understood that the figure is not necessarily drawn to scale.

Airlocks 742 and 746, also known as a loadlocks or transfer modules, interface with the VTM 738 and a patterning module 740. For example, as noted above, a suitable patterning module may be the TWINSCAN NXE: 3300B® platform supplied by ASML of Veldhoven, NL. This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a more conventional stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 7 but without the integrated patterning module.

Airlock 742 may be an “outgoing” loadlock, referring to the transfer of a substrate out from the VTM 738 serving a deposition module 720a to the patterning module 740, and airlock 746 may be an “ingoing” loadlock, referring to the transfer of a substrate from the patterning module 740 back in to the VTM 738. The ingoing loadlock 746 may also provide an interface to the exterior of the tool for access and egress of substrates. Each process module has a facet that interfaces the module to VTM 738. For example, deposition process module 720a has facet 736. Inside each facet, sensors, for example, sensors 1-18 as shown, are used to detect the passing of wafer 726 when moved between respective stations. Patterning module 740 and airlocks 742 and 746 may be similarly equipped with additional facets and sensors, not shown.

Main VTM robot 722 transfers wafer 726 between modules, including airlocks 742 and 746. In one embodiment, robot 722 has one arm, and in another embodiment, robot 722 has two arms, where each arm has an end effector 724 to pick wafers such as wafer 726 for transport. Front-end robot 744, in is used to transfer wafers 726 from outgoing airlock 742 into the patterning module 740, from the patterning module 740 into ingoing airlock 746. Front-end robot 744 may also transport wafers 726 between the ingoing loadlock and the exterior of the tool for access and egress of substrates. Because ingoing airlock module 746 has the ability to match the environment between atmospheric and vacuum, the wafer 726 is able to move between the two pressure environments without being damaged.

It should be noted that a EUVL tool typically operates at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 742 may provide this function by holding the transferred wafers at a lower pressure, no higher than the pressure in the patterning module 740, for a period of time and exhausting any off-gassing, so that the optics of the patterning tool 740 are not contaminated by off-gassing from the substrate. A suitable pressure for the outgoing, off-gassing airlock is no more than 1E-8 Torr.

In some embodiments, a system controller 750 (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 750 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative pattern mask is provided. The apparatus may include a processing chamber for patterning, deposition and etch, and a controller including instructions for forming a negative pattern mask. The instructions may include code for, in the processing chamber, patterning a feature in a chemically amplified (CAR) resist on a semiconductor substrate by EUV exposure to expose a surface of the substrate, dry developing the photopatterned resist, and etching the underlying layer or layer stack using the patterned resist as a mask.

It should be noted that the computer controlling the wafer movement can be local to the cluster architecture or can be located external to the cluster architecture in the manufacturing floor, or in a remote location and connected to the cluster architecture via a network.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A stack comprising:
a semiconductor substrate having a top surface;
a resist film disposed on the top surface of the semiconductor substrate, wherein the resist film comprises an Extreme Ultraviolet (EUV) photoresist; and
a hermetic overlayer disposed on a top surface of the resist film.

2. The stack of claim 1, wherein the hermetic overlayer is configured to protect the top surface of the resist film from absorbing one or more bond-terminating moieties from a gas phase.

3. The stack of claim 1, wherein the hermetic overlayer is EUV absorbing and configured to provide a directional primary photoelectron flux to the top surface of the resist film upon EUV irradiation; or wherein the hermetic overlayer is configured to generate one or more primary photoelectrons and/or secondary photoelectrons for injection from the hermetic overlayer to the resist film.

4. The stack of claim 1, wherein the hermetic overlayer has a thickness of about 1 nm to about 5 nm, and wherein the resist film optionally has a thickness of about 5 nm to about 200 nm.

5. The stack of claim 1, wherein the hermetic overlayer comprises a monolithic film or a bilayer, and wherein the bilayer comprises a lower layer comprising an alloy and an upper layer comprising an oxide.

6. The stack of claim 1, wherein the hermetic overlayer has a secondary emission yield of about 0.5 to about 2.

7. The stack of claim 1, wherein the hermetic overlayer comprises tin, tellurium, bismuth, an alloy thereof, an oxide thereof, or a complex oxide thereof, or a combination of any of these.

8. The stack of claim 1, wherein the EUV photoresist comprises an organometallic material.

9. The stack of claim 1, wherein the resist film comprises one or more EUV exposed areas and one or more EUV unexposed areas, and wherein a top surface of at least one EUV exposed area comprises an activated metal comprising one or more dangling bonds.

10. A method employing a positive tone resist, the method comprising:
depositing a resist film on a top surface of a semiconductor substrate, wherein the resist film comprises an Extreme Ultraviolet (EUV) photoresist;
applying a hermetic overlayer on a top surface of the resist film;
patterning the resist film through the hermetic overlayer by an EUV exposure having a wavelength in the range of about 10 nm to about 20 nm in a vacuum ambient, thereby providing EUV exposed areas and EUV unexposed areas; and
developing the resist film, thereby removing the EUV exposed areas and providing a pattern within the resist film.

11. The method of claim 10, wherein the hermetic overlayer is configured to generate one or more primary photoelectrons and/or secondary photoelectrons for injection from the hermetic overlayer to the resist film; or wherein the EUV exposure generates one or more primary photoelectrons and/or secondary photoelectrons for injection from the hermetic overlayer to the resist film.

12. The method of claim 10, further comprising, after said depositing:
baking the film, thereby providing a post-application bake (PAB) to remove one or more volatile components from the resist film prior to said applying.

13. The method of claim 12, wherein said applying is conducted at a lower temperature than said PAB, and wherein said applying optionally comprises thermal atomic layer deposition, spin coat deposition, electron beam vaporization, or a combination thereof.

14. The method of claim 10, further comprising, after said patterning:
stripping the hermetic overlayer, thereby providing a photoresist stack having the EUV exposed areas and the EUV unexposed areas.

15. The method of claim 14, further comprising, after said stripping:
conducting in situ metrology of the photoresist stack.

16. The method of claim 14, wherein said stripping comprises a thermal dry etch or a downstream plasma process; or wherein said stripping and said developing are conducted in vacuum without a vacuum break; or wherein said stripping and said developing are conducted employing HBr chemistry, or at a pressure of about 1 mTorr to about 100 mTorr, or at a temperature of about −10° C. to about 100° C.

17. The method of claim 10, further comprising, after said developing:
hardening the EUV unexposed areas, thereby providing a photoresist mask.

18. The method of claim 17, wherein said hardening comprises exposing with vacuum ultraviolet (VUV) in an oxygen (O₂), argon (Ar), helium (He), or carbon dioxide (CO₂) plasma environment; or wherein said hardening comprises annealing at a temperature of about 180° C. to about 240° C. in an air ambient environment or in an ozone/O₂ ambient environment.

19-24. (canceled)

25. An apparatus for depositing a hermetic overlayer, the apparatus comprising:
a deposition module comprising a chamber for depositing an Extreme Ultraviolet (EUV) photoresist as a resist film;
an application module comprising a chamber for applying a hermetic overlayer;
a patterning module comprising an EUV photolithography tool with a source of sub-30 nm wavelength radiation;
a development module comprising a chamber for stripping the hermetic overlayer and developing the resist film; and
a controller including one or more memory devices, one or more processors, and system control software coded with instructions for conducting hermetic overlayer deposition, the instructions comprising instructions for:
in the deposition module, causing deposition of the resist film on a top surface of a semiconductor substrate, wherein the resist film comprises the EUV photoresist;
in the application module, causing application of the hermetic overlayer on a top surface of the resist film;
in the patterning module, causing patterning of the resist film through the hermetic overlayer with sub-30 nm resolution directly by EUV exposure having a wavelength in the range of about 10 nm to about 20 nm in a vacuum ambient, thereby forming a pattern through the hermetic overlayer and within the resist film; and
in the development module, causing stripping of the hermetic overlayer to provide a photoresist stack comprising EUV exposed areas and EUV unexposed areas, and developing the resist film to remove the EUV exposed areas and to provide the pattern within the resist film,
wherein said causing stripping and said causing developing are optionally conducted in vacuum without a vacuum break.

26. The apparatus of claim 25, wherein the instructions further comprise:
in the development module, causing hardening of the EUV unexposed areas, thereby providing a photoresist mask.

27. The apparatus of claim 25, further comprising:
an in situ metrology module comprising a spectroscopy tool to analyze the photoresist stack.
